(19) United States
(12) Patent Application Publication
(10) Pub. No.: US 2025/0393342 A1
(43) Pub. Date: Dec. 25, 2025

(54) POLYCHROMATIC MULTI-JUNCTION LED

(71) Applicant: Lumileds LLC, San Jose, CA (US)

(72) Inventors: Robert Armitage, Cupertino, CA (US); Frank Zhongmin Ren, Danville, CA (US)

(73) Assignee: Lumileds LLC, San Jose, CA (US)

(21) Appl. No.: 18/751,511

(22) Filed: Jun. 24, 2024

(51) Int. Cl. H01L 33/00; H01L 33/04; H01L 33/32

(52) U.S. Cl. CPC H10H 20/813; H10H 20/0137; H10H 20/811; H10H 20/825

(57) ABSTRACT

Provided is a three p-n junction polychromatic LED compatible with synchronous driving of multiple junctions at low applied voltage. Semiconductor contact layers are isolated from each other by inserting epitaxial current blocking layers between them. Two of the p-n junctions are connected in parallel to the cathode (or anode) using the same n-type layer which allows for a configuration with only five terminals. The reduced number of contact terminals facilitates wafer fab processing and allows for a smaller pixel pitch or larger light-emitting area at a given pitch.

### TECHNICAL FIELD

Embodiments of the disclosure generally relate to light emitting diode (LED) devices and methods of manufacturing the same. More particularly, embodiments are directed to polychromatic multi-junction light emitting diode devices compatible with synchronous low-voltage driving.

### BACKGROUND

A light emitting diode (LED) is a semiconductor light source that emits visible light when current flows through it. LEDs combine a P-type semiconductor with an N-type semiconductor. LEDs commonly use a III-group compound semiconductor. A III-group compound semiconductor provides stable operation at a higher temperature than devices that use other semiconductors. The III-group compound is typically formed on a substrate formed of sapphire, silicon, or silicon carbide (SiC).

High-resolution color LED displays require microscopic pixel pitches. Assembling red, green, and blue LEDs grown on separate wafers becomes difficult when the sizes of the LEDs are in the range of tens of microns. Monolithic integration is an approach that avoids the need to manipulate microscopic LEDs into the right positions on the display but comes with its own set of challenges.

Know polychromatic micro-LED devices with three light-emitting n/p junctions and four contact terminals use tunnel junctions to avoid difficulty in making electrical contacts to p-type layers exposed by etching. While the design of such devices can emit any desired color within the required display gamut, it is not compatible with established methods for driving displays. In particular, two or more colors cannot be driven synchronously with low voltage because some of the same terminals which must be negatively biased to inject forward current into one junction must also be positively biased to inject current into the adjacent junction.

A design having six isolated contacts can avoid the synchronous driving problem, but the device fabrication becomes more difficult with larger numbers of contact vias. As the contact vias cannot be made arbitrarily small, the device footprint must be larger in a device with more vias (other things being equal). Moving from four to six vias, therefore, requires either sacrificing the light-emitting area or increasing the pixel pitch.

Four terminal devices that avoid the need for the same terminal to be both negatively and positively biased by using a sequence of n/p junctions having different stacking orders of the p and n-type layers are known. Such devices, however, are not compatible with established display driving methods using a common anode or common cathode.

Accordingly, there is a need for improved LED devices.

### SUMMARY

Embodiments of the disclosure are directed to LED devices and methods for manufacturing LED devices. In one or more embodiments, a light emitting diode (LED) device comprises: three p-n junctions grown sequentially on a substrate, the three p-n junctions including: a first p-n junction comprising a first light-emitting active region, a second p-n junction comprising a second light-emitting active region, and a third p-n junction comprising a third light-emitting active region, each of the three p-n junctions comprising an n-type layer and a p-type layer, one of the first p-n junction, the second p-n junction, or the third p-n junction having an n-type layer and a p-type layer grown in the opposite order of the n-type layer and p-type layer of the other of the first p-n junction, the second p-n junction, or the third p-n junction; an n/p tunnel junction; a p/n tunnel junction; and a current blocking layer disposed between two of the n-type layers.

Additional embodiments of the disclosure are directed to methods of manufacturing LED devices. In one or more embodiments, a method of manufacturing a light-emitting diode (LED) device comprises: epitaxially growing an epitaxial stack on a substrate, the epitaxial stack comprising three p-n junctions grown sequentially on the substrate, an n/p tunnel junction, a p/n tunnel junction, and a current blocking layer, wherein the three p-n junctions include a first p-n junction comprising a first light-emitting active region, a second p-n junction comprising a second light-emitting active region, and a third p-n junction comprising a third light-emitting active region, wherein one of the first p-n junction, the second p-n junction, or the third p-n junction has n-type layers and p-type layers grown in the opposite order of the n-type layers and p-type layers of the other of the first p-n junction, the second p-n junction, or the third p-n junction, and wherein the current blocking layer is disposed between two of the n-type layers.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1A illustrates a cross-section schematic of an epitaxy configuration according to one or more embodiments;

FIG. 1B illustrates a cross-section schematic of the epitaxy configuration of FIG. 1A including five terminal polychromatic LEDS according to one or more embodiments;

FIG. 2A illustrates a cross-section schematic of an epitaxy configuration according to one or more embodiments;

FIG. 2B illustrates a cross-section schematic of the epitaxy configuration of FIG. 2A including five terminal polychromatic LEDS according to one or more embodiments;

FIG. 3A illustrates a cross-section schematic of an epitaxy configuration according to one or more embodiments;

FIG. 3B illustrates a cross-section schematic of the epitaxy configuration of FIG. 3A including five terminal polychromatic LEDS according to one or more embodiments;

FIG. 4A illustrates a cross-section schematic of an epitaxy configuration according to one or more embodiments;

FIG. 4B illustrates a cross-section schematic of an enlarged portion of the epitaxy configuration of FIG. 4A according to one or more embodiments;

FIG. 4C illustrates a graph of the secondary ion mass spectrometry depth profile of impurities in an LED wafer with p-type layers grown before the quantum wells according to one or more embodiments;

FIG. 5A illustrates a cross-section schematic of an epitaxy configuration according to one or more embodiments;

FIG. 5B illustrates a cross-section schematic of an enlarged portion of the epitaxy configuration of FIG. 5A according to one or more embodiments;

FIG. 6A illustrates a cross-section schematic of an epitaxy configuration according to one or more embodiments;

FIG. 6B illustrates a cross-section schematic of the epitaxy configuration of FIG. 6A including five terminal polychromatic LEDS according to one or more embodiments;

FIG. 7A illustrates a cross-section schematic of an epitaxy configuration according to one or more embodiments;

FIG. 7B illustrates a cross-section schematic of the epitaxy configuration of FIG. 7A including five terminal polychromatic LEDS according to one or more embodiments;

FIG. 8A illustrates a cross-section schematic of an epitaxy configuration according to one or more embodiments;

FIG. 8B illustrates a cross-section schematic of the epitaxy configuration of FIG. 8A including five terminal polychromatic LEDS according to one or more embodiments;

FIG. 9A illustrates a cross-section schematic of an epitaxy configuration according to one or more embodiments;

FIG. 9B illustrates a cross-section schematic of the epitaxy configuration of FIG. 9A including five terminal polychromatic LEDS according to one or more embodiments;

FIG. 10A illustrates a cross-section schematic of an epitaxy configuration according to one or more embodiments;

FIG. 10B illustrates a cross-section schematic of the epitaxy configuration of FIG. 10A including five terminal polychromatic LEDS according to one or more embodiments;

FIG. 11A illustrates a cross-section schematic of an epitaxy configuration according to one or more embodiments;

FIG. 11B illustrates a cross-section schematic of the epitaxy configuration of FIG. 11A including five terminal polychromatic LEDS according to one or more embodiments;

FIG. 12 illustrates an example of a general device in accordance with some embodiments;

FIG. 13 illustrates an example display system, according to some embodiments;

FIG. 14 illustrates an example hardware arrangement for implementing the above disclosed subject matter, according to some embodiments; and

FIG. 15 shows a block diagram of an example of a system, according to some embodiments.

To facilitate understanding, identical reference numerals have been used, where possible, to designate identical elements that are common to the figures. The figures are not drawn to scale. For example, the heights and widths of the layers are not drawn to scale.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “substrate” as used herein according to one or more embodiments refers to a structure, intermediate or final, having a surface, or portion of a surface, upon which a process acts. In addition, reference to a substrate in some embodiments also refers to only a portion of the substrate, unless the context clearly indicates otherwise. Further, reference to depositing on a substrate according to some embodiments includes depositing on a bare substrate or on a substrate with one or more layers, films, features, or materials deposited or formed thereon.

In one or more embodiments, the “substrate” means any substrate or material surface formed on a substrate upon which film processing is performed during a fabrication process. In exemplary embodiments, a substrate surface on which processing is performed includes materials such as silicon, silicon oxide, silicon on insulator (SOI), strained silicon, amorphous silicon, doped silicon, carbon doped silicon oxides, germanium, gallium arsenide, glass, sapphire, and any other suitable materials such as metals, metal nitrides, III-nitrides (e.g., GaN, AlN, InN, and other alloys), metal alloys, and other conductive materials, depending on the application. Substrates include, without limitation, light emitting diode (LED) devices. Substrates in some embodiments are exposed to a pretreatment process to polish, etch, reduce, oxidize, hydroxylate, anneal, UV cure, e-beam cure and/or bake the substrate surface. In addition to film processing directly on the surface of the substrate itself, in some embodiments, any of the film processing steps disclosed is also performed on an underlayer formed on the substrate, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

The term “wafer” and “substrate” will be used interchangeably in the instant disclosure. Thus, as used herein, a wafer serves as the substrate for the formation of the LED devices described herein.

Examples of different light illumination systems and/or light emitting diode (LED) implementations will be described more fully hereinafter with reference to the accompanying drawings. These examples are not mutually exclusive, and features found in one example may be combined with features found in one or more other examples to achieve additional implementations. Accordingly, it will be understood that the examples shown in the accompanying drawings are provided for illustrative purposes only and they are not intended to limit the disclosure in any way. Like numbers refer to like elements throughout.

Semiconductor light emitting devices or optical power emitting devices, such as devices that emit ultraviolet (UV) or infrared (IR) optical power, are among the most efficient light sources currently available. These devices may include light emitting diodes, resonant cavity light emitting diodes, vertical cavity laser diodes, edge emitting lasers, or the like (hereinafter referred to as “LEDs”). Due to their compact size and lower power requirements, for example, LEDs may be attractive candidates for many different applications. For example, they may be used as light sources (e.g., flashlights and camera flashes) for hand-held battery-powered devices, such as cameras and cell phones. They may also be used, for example, for automotive lighting, heads up display (HUD) lighting, horticultural lighting, street lighting, torch for video, general illumination (e.g., home, shop, office and studio lighting, theater/stage lighting and architectural lighting), augmented reality (AR) lighting, virtual reality (VR) lighting, as back lights for displays, and IR spectroscopy. A single LED may provide light that is less bright than an incandescent light source, and, therefore, multi-junction devices or arrays of LEDs (such as monolithic LED arrays, micro-LED arrays, etc.) may be used for applications where more brightness is desired or required.

The present disclosure generally relates to the manufacture of polychromatic LED devices that can be used in high resolution color displays.

Embodiments described herein describe LED devices and methods for forming LED devices. In one or more embodiments, the LED device designs advantageously have fewer than six contacts and are capable of high efficiency and also compatible with synchronous driving using a common terminal (common cathode or common anode). In particular, the present disclosure describes three-junction polychromatic LEDs compatible with synchronous driving of multiple junctions at low applied voltage. In one or more embodiments, the semiconductor contact layers are isolated from each other by inserting epitaxial current blocking layers between them. Two of the junctions are connected in parallel to the cathode (or anode) using the same n-type layer, allowing for a configuration with only five terminals (rather than six terminals, as existing LEDs have). The reduced number of contacts terminals facilitates wafer fab processing and allows for a smaller pixel pitch or larger light-emitting area at a given pitch. In one or more embodiments improvements to the epitaxy minimize undesired diffusion of dopants and point defects and increase the internal quantum efficiency (IQE) of quantum wells grown after p/n tunnel junctions, which is otherwise expected to be low.

As used herein, the term “p-n junction” refers to a boundary between two semiconductor layers of opposite conductivity types p-type and n-type. The “p” side contains an excess of holes, while the “n” side contains an excess of electrons. The excesses of holes and electrons may be obtained by intentional doping with acceptor or donor impurities, respectively, and/or may result from the presence of native crystal defects. Said boundary is not necessarily abrupt, planar, or smooth. Said boundary may include of gradients in impurity concentration and/or layers of intrinsic (neutral) conductivity type between the p-type and n-type layers. Said boundary may feature protrusions of p-type semiconductor into the n-type semiconductor, or vice-versa.

One or more embodiments requires three p-n junctions to be grown sequentially on the same epitaxial wafer. One of these junctions has the opposite order of deposition of the n- and p-layers as compared to the others. In one or more embodiments, light-emitting active regions of the three primary colors—red, blue, and green—are disposed between the n- and p-layers of each of the p-n junctions. The active regions may be comprised of an InGaN quantum well or wells, or layers doped with an optically active transition metal such as GaN:Eu. In one or more embodiments, the epitaxial wafer includes at least two tunnel junctions. One tunnel junction is an n/p tunnel junction and the other one is a p/n tunnel junction, referring to the order of layer growth.

In one or more embodiments, the epitaxial wafer includes a current blocking layer “sandwiched” between two n-type layers, and, in the processed device, two separate contact vias are etched to independently contact each of those two n-type layers. As used herein, the term “sandwich” refers to the plurality of layers including a current blocking layer between two n-type layers. In one or more embodiments, one of the light-emitting junctions described is disposed on one side of the sandwich, and a light-emitting junction having opposite growth order of n- and p-layers is disposed on the opposite side of the sandwich.

In one or more embodiments, the current blocking layer in the sandwich may be comprised of any of the following: a p-type layer, a weakly n-type (semi-insulating) layer, or a layer of different semiconductor alloy composition exhibiting a conduction band offset of more than 0.1 eV with respect to the adjacent n-type layers, such as an AlGaN or InGaN layer sandwiched between n-type GaN layers. Semi-insulating layers may be realized by doping with deep-level impurities such as carbon or iron, at a concentration equal to or greater than the total concentration of donor impurities, e.g., silicon (Si), germanium (Ge), and oxygen (O).

In some embodiments, the epitaxial wafer includes “diffusion blocking” layers, which are layers grown for the purpose of hindering detrimental diffusion of point defects and impurities in the direction perpendicular to the substrate wafer plane during growth or post-growth annealing steps. In one or more embodiments, as illustrated in the Figures, the diffusion blocking layers may be incorporated in n-type and/or p-type layers, which are grown immediately after a tunnel junction.

In one or more embodiments, the diffusion blocking layers may be comprised of a short-period superlattice of semiconductor alloy layers having different lattice constants, such as, but not limited to, GaN and InGaN or AlGaN, or layers co-doped with magnesium (Mg) and silicon (Si) but having an overall p-type conductivity due to a higher concentration of Mg versus Si.

In some embodiments, a third (p/n) tunnel junction may be included in the epitaxy wafer, allowing all of the electrical contacts to be made to n-type layers. Other embodiments may use transparent conducting oxide materials, e.g., indium tin oxide (ITO), or metal contacts on p-GaN for the purposes of current injection and spreading.

In one or more embodiments, the processed device wafer includes other contact vias, metallization, and dielectric isolation layers, as illustrated in the Figures. As illustrated, different configurations of the contact vias are possible for flip chip versus substrate-attached embodiments, and for common cathode versus common anode embodiments.

The embodiments of the disclosure are described by way of the Figures, which illustrate devices and processes for forming devices in accordance with one or more embodiments of the disclosure. The processes shown are merely illustrative possible uses for the disclosed processes, and the skilled artisan will recognize that the disclosed processes are not limited to the illustrated applications.

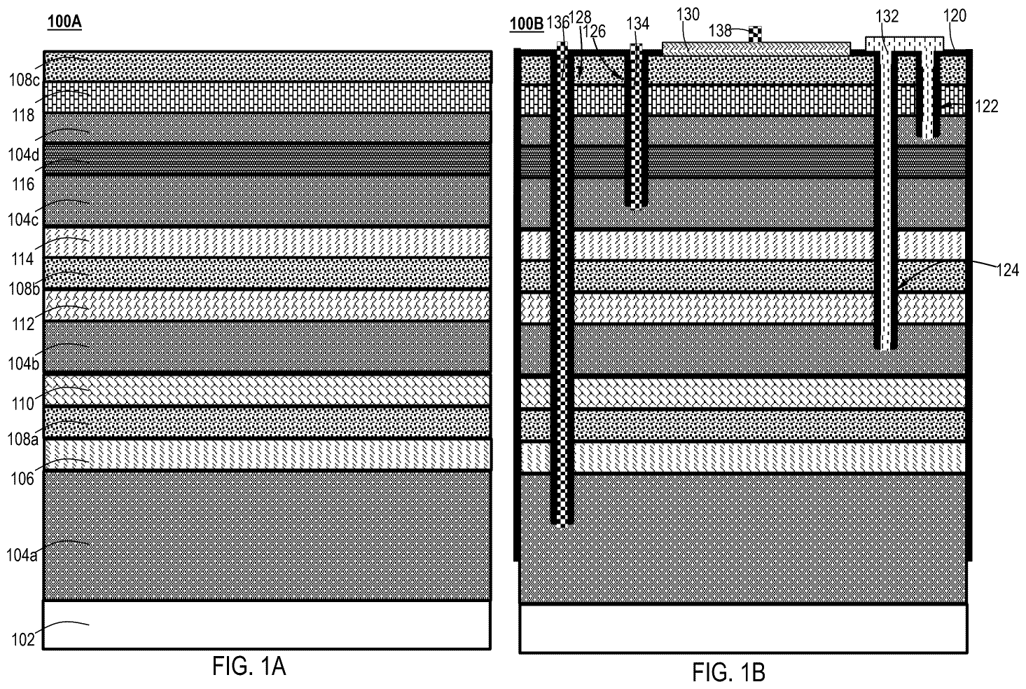

One or more embodiments of the disclosure are described with reference to the Figures. FIG. 1A illustrates a cross-sectional schematic of an epitaxy configuration 100A according to one or more embodiments. FIG. 1B illustrates a cross-section schematic of the epitaxy configuration of FIG. 1A including five terminal polychromatic LEDS according to one or more embodiments. While the drawings show functional elements (e.g., n-type layers, p-type layers, and the like) with individual shaded rectangles, it should be understood that these rectangles can represent a composite laminate of several layers of the same conductivity type (n-type or p-type) but with differences in the doping concentrations or alloy mole fractions.

Referring to FIG. 1A and FIG. 1B, a three-junction polychromatic LED 100B is manufactured by forming an epitaxial stack 100A having three-light emitting active regions. The epitaxial stack 100A includes plurality of III-nitride layers on a substrate 102 to form three p-n junction LEDs on the substrate, one of the p-n junctions having the opposite order of deposition of the n- and p-layers as compared to the others.

According to certain specific embodiments, the first light emitting region of the three-junction polychromatic LED 100A/100B comprises a first n-type layer 104a on the substrate 102.

In one or more embodiments, a nucleation layer (not illustrated) and dislocation density control layers (not illustrated) may be grown on a suitable substrate 102, such as patterned or non-patterned sapphire. In one or more embodiments, the nucleation layer comprises a III-nitride material. In specific embodiments, the nucleation layer comprises gallium nitride (GaN) or aluminum nitride (AlN).

In one or more embodiments, first n-type layer 104a is grown on the substrate 102, the nucleation layer, and/or the dislocation density control layers. In one or more embodiments, a first n-type layer 104a is formed on the substrate 102. The substrate 102 may be any substrate known to one of skill in the art which is configured for use in the formation of LED devices. In one or more embodiments, the substrate 102 comprises one or more of sapphire, silicon carbide, silicon (Si), quartz, magnesium oxide (MgO), zinc oxide (ZnO), spinel, and the like. In one or more embodiments, the substrate 102 is a transparent substrate. In specific embodiments, the substrate 102 comprises sapphire. In one or more embodiments, the substrate 102 is not patterned prior to formation of the LEDs. Thus, in some embodiments, the substrate is 102 not patterned and can be considered to be flat or substantially flat. In other embodiments, the substrate 102 is a patterned substrate.

In one or more embodiments, the first n-type layer 104a, the second n-type layer 104b, the third n-type layer 104c, and the fourth n-type layer 104d may comprise any Group III-V semiconductors, including binary, ternary, and quaternary alloys of gallium (Ga), aluminum (Al), indium (In), and nitrogen (N), also referred to as III-nitride materials. Thus, in some embodiments, the first n-type layer 104a, the second n-type layer 104b, the third n-type layer 104c, and the fourth n-type layer 104d independently comprise one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like. In a specific embodiment, the first n-type layer 104a, the second n-type layer 104b, the third n-type layer 104c, and the fourth n-type layer 104d comprise gallium nitride (GaN) of aluminum gallium nitride (AlGaN). In one or more embodiments, the first n-type layer 104a, the second n-type layer 104b, the third n-type layer 104c, and the fourth n-type layer 104s are independently doped with n-type dopants, such as silicon (Si) or germanium (Ge). In one or more embodiments, the dopant concentration is in a range of from 1e17 to 2e19 cm⁻³. In one or more embodiments, the first n-type layer 104a may have a thickness in the range of from 1 μm to 3 μm to ensure a wide process margin for a subsequent etching step used to contact this layer.

In one or more embodiments, the layers of III-nitride material may be deposited by one or more of sputter deposition, atomic layer deposition (ALD), metalorganic chemical vapor deposition (MOCVD), physical vapor deposition (PVD), plasma enhanced atomic layer deposition (PEALD), and plasma enhanced chemical vapor deposition (PECVD).

“Sputter deposition” as used herein refers to a physical vapor deposition (PVD) method of thin film deposition by sputtering. In sputter deposition, a material, e.g., a III-nitride, is ejected from a target that is a source onto a substrate. The technique is based on ion bombardment of a source material, the target. Ion bombardment results in a vapor due to a purely physical process, i.e., the sputtering of the target material.

As used according to some embodiments herein, “atomic layer deposition” (ALD) or “cyclical deposition” refers to a vapor phase technique used to deposit thin films on a substrate surface. The process of ALD involves the surface of a substrate, or a portion of substrate, being exposed to alternating precursors, i.e., two or more reactive compounds, to deposit a layer of material on the substrate surface. When the substrate is exposed to the alternating precursors, the precursors are introduced sequentially or simultaneously. The precursors are introduced into a reaction zone of a processing chamber, and the substrate, or portion of the substrate, is exposed separately to the precursors.

As used herein according to some embodiments, “chemical vapor deposition” refers to a process in which films of materials are deposited from the vapor phase by decomposition of chemicals on a substrate surface. In CVD, a substrate surface is exposed to precursors and/or co-reagents simultaneously or substantially simultaneously. A particular subset of CVD processes commonly used in LED manufacturing use metalorganic precursor chemical and are referred to as MOCVD or metalorganic vapor phase epitaxy (MOVPE). As used herein, “substantially simultaneously” refers to either co-flow or where there is overlap for a majority of exposures of the precursors.

As used herein according to some embodiments, “plasma enhanced atomic layer deposition (PEALD)” refers to a technique for depositing thin films on a substrate. In some examples of PEALD processes relative to thermal ALD processes, a material may be formed from the same chemical precursors, but at a higher deposition rate and a lower temperature. In a PEALD process, in general, a reactant gas and a reactant plasma are sequentially introduced into a process chamber having a substrate in the chamber. The first reactant gas is pulsed in the process chamber and is adsorbed onto the substrate surface. Thereafter, the reactant plasma is pulsed into the process chamber and reacts with the first reactant gas to form a deposition material, e.g., a thin film on a substrate. Similar to a thermal ALD process, a purge step may be conducted between the deliveries of each of the reactants.

As used herein according to one or more embodiments, “plasma enhanced chemical vapor deposition (PECVD)” refers to a technique for depositing thin films on a substrate. In a PECVD process, a source material, which is in gas or liquid phase, such as a gas-phase III-nitride material or a vapor of a liquid-phase III-nitride material that have been entrained in a carrier gas, is introduced into a PECVD chamber. A plasma-initiated gas is also introduced into the chamber. The creation of plasma in the chamber creates excited radicals. The excited radicals are chemically bound to the surface of a substrate positioned in the chamber, forming the desired film thereon.

In one or more embodiments, μLED stack 100A is manufactured by placing the substrate 102 in a metalorganic vapor-phase epitaxy (MOVPE) reactor so that the μLED array layers are grown epitaxially.

As described above, and as illustrated in FIGS. 1A and 1B, in one or more embodiments, after the growth of the first n-type layer 104a, an n/p tunnel junction 106 is grown.

A tunnel junction is a structure that allows electrons to tunnel from the valence band of a p-type layer to the conduction band of an n-type layer in reverse bias. When an electron tunnels, a hole is left behind in the p-type layer, such that carriers are generated in both regions. Accordingly, in an electronic device like a diode, where only a small leakage current flows in reverse bias, a large current can be carried in reverse bias across a tunnel junction. A tunnel junction comprises a particular alignment of the conduction and valence bands at the p/n tunnel junction. This can be achieved by using very high doping (e.g., in the p++/n++ junction). In addition, III-nitride materials have an inherent polarization that creates an electric field at heterointerfaces between different alloy compositions. In some circumstances, this polarization field can also be utilized to achieve band alignment for tunneling. For a p-GaN/InGaN/n-GaN configuration, the polarization field and p-n junction field align in the same direction, which is favorable to enhance tunneling (larger band bending larger and shorter tunneling distance). For a n-GaN/InGaN/p-GaN configuration, the polarization field and n-p junction field align in opposite directions. Therefore, it is generally harder to obtain a low-resistance tunnel junction with the n/p order.

In one or more embodiments, the n/p tunnel junction 106 is comprised of heavily doped p-GaN and n-GaN layers with doping concentrations in the range 10¹⁹-10²¹ cm⁻³ and layer thickness typically less than 50 nm. The n/p tunnel junction 106 may also utilize thin InGaN or graded InGaN layers disposed between highly doped GaN layers. In one or more embodiments, the AlN layer has opposite polarization direction versus an InGaN layer. Therefore, AlN has the “correct” polarization to enhance tunneling in a n-GaN/AlN/p-GaN configuration. However, the band gap of AlN is very large so the tunneling current is still not very high. In one or more embodiments, the n/p tunnel junction 106 is comprised of a very heavily doped (>1e10²⁰) GaN:Mg layer grown after a very heavily doped GaN:Si or GaN:Ge layer, with an optional thin (<3 nm) AlN or AlGaN layer inserted between them.

Still referring to FIG. 1A and FIG. 1B, the first light emitting region includes a first p-type layer 108a on the n/p tunnel junction 106. In one or more embodiments, the first p-type layer 108a, the second p-type layer 108b, and the third p-type layer 108c may independently comprise any Group III-V semiconductors, including binary, ternary, and quaternary alloys of gallium (Ga), aluminum (Al), indium (In), and nitrogen (N), also referred to as III-nitride materials. Thus, in some embodiments, the first p-type layer 108a, the second p-type layer 108b, and the third p-type layer 108c independently comprise one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like. In one or more embodiments, magnesium (Mg) is the acceptor dopant for the first p-type layer 108a.

In some embodiments, the first p-type layer 108a and the second p-type layer 108b independently comprise a sequence of doped p-type layers. In one or more embodiments, the first p-type layer 108a and the second p-type layer 108b independently comprise a gallium nitride (GaN) layer. The first p-type layer 108a and the second p-type layer 108b may be independently doped with any suitable p-type dopant known to the skilled artisan. In one or more embodiments, the first p-type layer 108a and the second p-type layer 108b may independently be doped with magnesium (Mg). In one or more embodiments, the first p-type layer 108a and the second p-type layer 108b independently comprise a first magnesium doped p-type aluminum gallium nitride layer, a magnesium doped p-type gallium nitride layer, and a second magnesium doped p-type aluminum gallium nitride layer. In one or more embodiments, the p-type layers comprise GaN or AlGaN doped with Mg in the range 10¹⁸-10²⁰ per cm⁻³.

After growth of the first p-type layer 108a on the n/p tunnel junction 106, a first light-emitting active region 110 is grown. In one or more embodiments, the first active region 110 is a blue active region.

In one or more embodiments, the first light-emitting active region 110, and also the second light-emitting active region 112, and the third light-emitting active region 118, includes multiple quantum wells and may include electron blocking layer(s) grown after the quantum wells and strain-control layers grown before the quantum wells. The process of growing the strain-control layers may generate V-pit defects before the growth of the first quantum well. The number of quantum wells typically used for blue LEDs ranges from 1 to 12, the typical barrier thickness ranges from 3 nm to 20 nm, the well thickness ranges from 1 nm to 5 nm, and the well indium concentration ranges from 10% indium to 20% indium. In some embodiments, the active region(s) may be doped with Si or Ge, while in other embodiments, the active region(s) is undoped. In one or more embodiments, the first light-emitting active region 110, the second light-emitting active region 112, and the third light-emitting active region 118 may be comprised of an InGaN quantum well or wells, or layers doped with an optically active transition metal such as GaN:Eu. In one or more embodiments, the active regions 110, 112, 118 are comprised of one or more InGaN quantum wells with GaN or AlGaN barrier layers and usually a progressively higher % indium (In) in the quantum well(s) for blue, green, and red active regions. In some embodiments the quantum wells of different colors may have similar % In but differences in well width and/or barrier layer composition to adjust the emission wavelength

After the first light-emitting active region 110 is grown, a second n-type layer 104b is grown on the first light-emitting active region 110.

Still referring to FIG. 1A and FIG. 1B, in one or more embodiments, after the second n-type layer 104b is grown, second light-emitting active region 112 is grown. In one or more embodiments, the second active region 112 is a green active region.

The general range of parameter limits is the same for the second light-emitting active region 112 as for the first light-emitting active region 110, however some differences in specific details may be needed to obtain similar characteristics for the first and second active regions having opposite polarities.

In one or more embodiments, a second p-type layer 108b is formed on the second active region 112, followed by the growth of a p/n tunnel junction 114. It is noted that the p/n tunnel junction 114 has layers that are grown in an order that is opposite the layers of the n/p tunnel junction 110. In one or more embodiments, the p/n tunnel junction 114 is comprised of a heavily doped ((>1e10¹⁹) GaN:Si or GaN:Ge layer grown after a heavily doped GaN:Mg layer, with an optional thin InGaN layer inserted between them. The optional thin InGaN layer may have a graded % In composition.

Still referring to FIG. 1A and FIG. 1B, a third light emitting region is then formed on the second light emitting region. The third light emitting region includes a third n-type layer 104c on the first p/n tunnel junction 114. A current blocking layer 116 is on the third n-type layer 104c. In one or more embodiments, the current blocking layer 116 is sandwiched between the third n-type layer 104c and a fourth n-type layer 104d. In one or more embodiments, a light-emitting junction is on one side of the current blocking layer 116 and a second light-emitting junction having opposite growth order of n- and p-layers is disposed on the opposite side of the current blocking layer 116. In one or more embodiments, in the processed device 100B, two separate contact vias 126,128 are etched to independently contact each of those two n-type layers.

In one or more embodiments, the current blocking layer 116 may include one or more of a p-type layer, a weakly n-type (semi-insulating) layer, or a layer of different semiconductor alloy composition exhibiting a conduction band offset of more than 0.1 eV with respect to the adjacent n-type layers, such as, but not limited to, an AlGaN or InGaN layer sandwiched between n-type GaN layers. Semi-insulating layers may be realized by doping with deep-level impurities such as carbon (C) or iron (Fe), at a concentration equal to or greater than the total concentration of donor impurities silicon (Si), germanium (Ge), and oxygen (O).

A third light-emitting active region 118 is on the fourth n-type layer. In one or more embodiments, the third active region 118 is a red active region. In one or more embodiments, the red active region, in particular, may alternatively be comprised of a GaN layer doped with Eu and optional co-dopants such as O or Mg. Such a layer emits red light via transitions between internal energy levels of the Eu dopants. Alternatively, the red active region may be compromised of InGaN quantum well(s) as described above with suitable design changes to adjust the wavelength.

In one or more embodiments, the epitaxy of the stack 100A is ended with growth of a third p-type layer 108c on the third active region 118. The Mg doping concentration may be increased near the surface of layer 108c to facilitate ohmic contact formation with metal or conducting transparent oxide electrodes.

As illustrated in FIG. 1B, after epitaxial growth, the epitaxial stack 100A is processed through fabrication steps to form a five terminal, three-junction polychromatic LED device 100B.

In one or more embodiments, four sets of vias 122, 124, 126, and 128 are formed by lithography and dry etching. In the Figures, the vias are shown with vertical side walls, but in actual devices the side walls may have one or more angles that can differ from vertical by up to 60 degrees. The vias 122, 124, 126, and 128 have different depths, D1, D2, D3, and D4. In one or more embodiments, the via 122 can have a depth D1 in a range from 0.1 microns to 1.0 microns such that the via 122 terminates in the fourth n-type layer 104d. In one or more embodiments, the via 124 can have a depth D2 in a range from 0.4 microns to 3 microns such that the via 124 terminates in second n-type layer 104b. In one or more embodiments, the via 126 can have a depth D3 in a range from 0.4 microns to 2 microns such that the via 126 terminates in third n-type layer 104c. In one or more embodiments, the via 128 can have a depth D3 in a range from 0.5 microns to 3 microns such that the via 128 terminates in first n-type layer 104a.

The epitaxy stack may then be subjected to an acceptor activation anneal. In some embodiments, it is preferable to do the acceptor activation anneal after dry etching in order to allow for hydrogen to escape buried p-type layers through the via side walls.

In one or more embodiments, a dielectric layer 120 is deposited in the vias 122, 124, 126, 128. As used herein, the term “dielectric” refers to an electrical insulator material that can be polarized by an applied electric field. In one or more embodiments, the dielectric layer includes, but is not limited to, oxides, e.g., silicon oxide (SiO₂), aluminum oxide (Al₂O₃), nitrides, e.g., silicon nitride (Si₃N₄). In one or more embodiments, the dielectric layer comprises silicon nitride (Si₃N₄), silicon oxide (SiO₂), or a multi-layer of silicon dioxide (SiO₂) and silicon nitride (Si₃N₄). In some embodiments, the dielectric layer composition is non-stoichiometric relative to the ideal molecular formula. For example, in some embodiments, the dielectric layer includes, but is not limited to, oxides (e.g., silicon oxide, aluminum oxide), nitrides (e.g., silicon nitride (SiN)), oxycarbides (e.g., silicon oxycarbide (SiOC)), and oxynitrocarbides (e.g., silicon oxycarbonitride (SiNCO)).

In one or more embodiments, the dielectric layer 120 is patterned using lithography and wet or dry etching to leave openings for metal to contact the semiconductor at desired locations. In one or more embodiments, a portion of the dielectric layer 120 is removed with dry etching to form an opening where transparent conductive layer 130 is deposited. In one or more embodiments, the transparent conductive layer 130 comprises one or more of indium tin oxide (ITO), zinc oxide (ZnO), or indium zinc oxide (IZO) and is deposited by PVD to make electrical contact to the third p-type layer 108c and facilitate current spreading. The transparent conductor layer 130 typically has a thickness between 10 and 200 nm and it optionally may be annealed after deposition to improve its transparency or electrical conductivity. For connection to driver circuitry an opaque metal layer 138 may be deposited over a small portion of the area of the transparent conductor as shown in FIG. 1B.

Contact metals are typically deposited in the via openings after dielectric layer 120 patterning using a physical vapor deposition (PVD) technique such as evaporation or sputtering.

A cathode metal layer 132 is deposited into the opening defined by vias 122, 124 along the sidewalls of the vias 122,124, which are lined with dielectric layer 120. The cathode metal layer 132 may comprise any suitable material known to the skilled artisan. In one or more embodiments, the cathode metal layer 132 is any high reflectivity metal that makes ohmic contact with the n-type layers. In one or more specific embodiments, the cathode metal layer 132 comprises an n-contact material selected from one or more of silver (Ag) and aluminum (Al). In one or more embodiments, the cathode metal layer 132 forms the common cathode.

An anode metal layer 134, 136 is deposited into the opening defined by vias 126, 128, respectively, along the sidewalls of the vias 126,128, which are lined with dielectric layer 120. The anode metal layer 134, 138 may comprise any suitable material known to the skilled artisan. In one or more embodiments, the cathode metal layer 134, 136 is any high reflectivity metal that makes ohmic contact with the n-type layers. In one or more specific embodiments, the anode metal layer 134, 136 comprises an n-contact material selected from one or more of silver (Ag) and aluminum (Al).

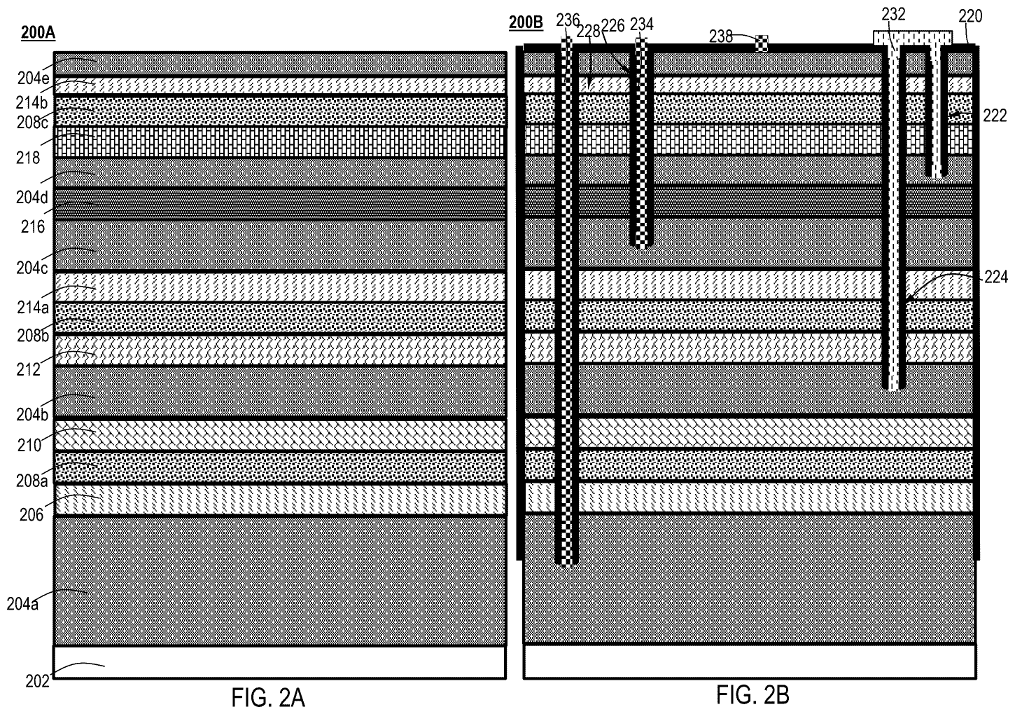

FIG. 2A illustrates a cross-sectional schematic of an epitaxy configuration 200A according to one or more embodiments. FIG. 2B illustrates a cross-section schematic of the epitaxy configuration of FIG. 2A including five terminal polychromatic LEDS according to one or more embodiments.

Referring to FIG. 2A and FIG. 2B, a three-junction polychromatic LED 200B is manufactured by forming an epitaxial stack 200A having three-light emitting active regions. The epitaxial stack 200A includes plurality of III-nitride layers on a substrate 202 to form three p-n junction LEDs on the substrate, one of the p-n junctions having the opposite order of deposition of the n- and p-layers as compared to the others.

According to certain specific embodiments, the first light emitting region of the three-junction polychromatic LED 200A/200B comprises a first n-type layer 204a on the substrate 202.

As described above with respect to FIGS. 1A-1B, in one or more embodiments, a nucleation layer (not illustrated) and dislocation density control layers (not illustrated) may be grown on a suitable substrate 202, such as patterned or non-patterned sapphire. In one or more embodiments, the nucleation layer comprises a III-nitride material. In specific embodiments, the nucleation layer comprises gallium nitride (GaN) or aluminum nitride (AlN).

In one or more embodiments, first n-type layer 204a is grown on the substrate 202, the nucleation layer, and/or the dislocation density control layers. In one or more embodiments, a first n-type layer 204a is formed directly on the substrate 202. The substrate 202 may be any substrate known to one of skill in the art which is configured for use in the formation of LED devices, including those described above with respect to substrate 102.

In one or more embodiments, the first n-type layer 204a, the second n-type layer 204b, the third n-type layer 204c, the fourth n-type layer 204d, and the fifth n-type layer 205e may comprise any Group III-V semiconductors, including binary, ternary, and quaternary alloys of gallium (Ga), aluminum (Al), indium (In), and nitrogen (N), also referred to as III-nitride materials as described above with respect to the n-type layers 104.

In one or more embodiments, the layers of III-nitride material may be deposited by one or more of sputter deposition, atomic layer deposition (ALD), metalorganic chemical vapor deposition (MOCVD), physical vapor deposition (PVD), plasma enhanced atomic layer deposition (PEALD), and plasma enhanced chemical vapor deposition (PECVD), as described above with respect to the n-type layers 104.

In one or more embodiments, μLED stack 200A is manufactured by placing the substrate 202 in a metalorganic vapor-phase epitaxy (MOVPE) reactor so that the μLED array layers are grown epitaxially.

As described above, and as illustrated in FIGS. 2A and 2B, in one or more embodiments, after the growth of the first n-type layer 204a, an n/p tunnel junction 206 is grown.

In one or more embodiments, the n/p tunnel junction 206 is comprised of heavily doped p-GaN and n-GaN layers with doping concentrations in the range 10¹⁹-10²¹ cm⁻³ and layer thickness typically less than 50 nm. The n/p tunnel junction 206 may also utilize thin InGaN or graded InGaN layers disposed between highly doped GaN layers. In one or more embodiments, the n/p tunnel junction 206 is comprised of a very heavily doped (>1e10²⁰) GaN:Mg layer grown after a very heavily doped GaN:Si or GaN:Ge layer, with an optional thin (<3 nm) AlN or AlGaN layer inserted between them.

Still referring to FIG. 2A and FIG. 2B, the first light emitting region includes a first p-type layer 208a on the n/p tunnel junction 206. In one or more embodiments, the first p-type layer 208a, the second p-type layer 208b, and the third p-type layer 208c may independently comprise any Group III-V semiconductors, including binary, ternary, and quaternary alloys of gallium (Ga), aluminum (Al), indium (In), and nitrogen (N), also referred to as III-nitride materials, as described above with respect to the p-type layers 108.

After growth of the first p-type layer 208a on the n/p tunnel junction 206, a first light-emitting active region 210 is grown. In one or more embodiments, the first active region 210 is a blue active region.

In one or more embodiments, the first light-emitting active region 210, and also the second light-emitting active region 212, and the third light-emitting active region 218, includes multiple quantum wells and may include electron blocking layer(s) grown after the quantum wells and strain-control layers grown before the quantum wells. The process of growing the strain-control layers may generate V-pit defects before the growth of the first quantum well. The number of quantum wells typically used for blue LEDs ranges from 1 to 12, the typical barrier thickness ranges from 3 nm to 20 nm, the well thickness ranges from 1 nm to 5 nm, and the well indium concentration ranges from 10% indium to 20% indium. In some embodiments, the active region(s) may be doped with Si or Ge, while in other embodiments, the active region(s) is undoped. In one or more embodiments, the first light-emitting active region 210, the second light-emitting active region 212, and the third light-emitting active region 218 may be comprised of an InGaN quantum well or wells, or layers doped with an optically active transition metal such as GaN:Eu. In one or more embodiments, the active regions 210, 212, 218 are comprised of one or more InGaN quantum wells with GaN or AlGaN barrier layers and usually a progressively higher % indium (In) in the quantum well(s) for blue, green, and red active regions. In some embodiments the quantum wells of different colors may have similar % In but differences in well width and/or barrier layer composition to adjust the emission wavelength.

After the first light-emitting active region 210 is grown, a second n-type layer 204b is grown on the first light-emitting active region 210.

Still referring to FIG. 2A and FIG. 2B, in one or more embodiments, after the second n-type layer 204b is grown, a second light-emitting active region 212 is grown. In one or more embodiments, the second active region 212 is a green active region.

The general range of parameter limits is the same for the second light-emitting active region 212 as for the first light-emitting active region 210, however some differences in specific details may be needed to obtain similar characteristics for the first and second active regions having opposite polarities.

In one or more embodiments, a second p-type layer 208b is formed on the second active region 212, followed by the growth of a first p/n tunnel junction 214a. It is noted that the first p/n tunnel junction 214a and the second p/n tunnel junction 214b have layers that are grown in an order that is opposite the layers of the n/p tunnel junction 210. In one or more embodiments, the first p/n tunnel junction 214a and the second p/n tunnel junction 214b may be comprised of a heavily doped ((>1e10¹⁹) GaN:Si or GaN:Ge layer grown after a heavily doped GaN:Mg layer, with an optional thin InGaN layer inserted between them. The optional thin InGaN layer may have a graded % In composition.

Still referring to FIG. 2A and FIG. 2B, a third light emitting region is then formed on the second light emitting region. The third light emitting region includes a third n-type layer 204c on the first p/n tunnel junction 214a. A current blocking layer 216 is on the third n-type layer 1204c. In one or more embodiments, as described above with respect to the current blocking layer 116, the current blocking layer 216 is sandwiched between the third n-type layer 204c and a fourth n-type layer 204d. In one or more embodiments, a light-emitting junction is on one side of the current blocking layer 216 and a second light-emitting junction having opposite growth order of n- and p-layers is disposed on the opposite side of the current blocking layer 216. In one or more embodiments, in the processed device 200B, two separate contact vias 224, 226 are etched to independently contact each of those two n-type layers.

A third light-emitting active region 218 is on the fourth n-type layer 204d. In one or more embodiments, the third active region 218 is a red active region. In one or more embodiments, the red active region, in particular, may alternatively be comprised of a GaN layer doped with Eu and optional co-dopants such as O or Mg. Such a layer emits red light via transitions between internal energy levels of the Eu dopants. Alternatively, the red active region may be compromised of InGaN quantum well(s) as described above with suitable design changes to adjust the wavelength.

In one or more embodiments, a third p-type layer 208c on the third active region 218. A second p/n tunnel junction 214b is on the third p-type layer 208c. In one or more embodiments, the epitaxy of the stack 200A is ended with growth of a fifth n-type layer 204e.

As illustrated in FIG. 2B, after epitaxial growth, the epitaxial stack 200A is processed through fabrication steps to form a five terminal, three-junction polychromatic LED device 200B.

In one or more embodiments, four sets of vias 222, 224, 226, and 228 are formed by lithography and dry etching. The vias 222, 224, 226, and 228 have different depths, D1, D2, D3, and D4. In one or more embodiments, the via 222 can have a depth D1 in a range from 0.1 microns to 1.0 microns such that the via 222 terminates in the fourth n-type layer 104d. In one or more embodiments, the via 224 can have a depth D2 in a range from 0.4 microns to 3 microns such that the via 124 terminates in second n-type layer 204b. In one or more embodiments, the via 226 can have a depth D3 in a range from 0.4 microns to 2 microns such that the via 226 terminates in third n-type layer 204c. In one or more embodiments, the via 228 can have a depth D3 in a range from 0.4 microns to 3 microns such that the via 228 terminates in first n-type layer 204a.

The epitaxy stack may then be subjected to an acceptor activation anneal, as described above with respect to the epitaxy stack in FIGS. 1A and 1B.

In one or more embodiments, a dielectric layer 220 is deposited in the vias 222, 224, 226, 228, as described above with respect to dielectric layer 120. In some embodiments, the dielectric layer 220 includes, but is not limited to, oxides (e.g., silicon oxide, aluminum oxide), nitrides (e.g., silicon nitride (SiN)), oxycarbides (e.g., silicon oxycarbide (SiOC)), and oxynitrocarbides (e.g., silicon oxycarbonitride (SiNCO)).

In one or more embodiments, the dielectric layer 220 is patterned using lithography and wet or dry etching to leave openings for metal to contact the semiconductor at desired locations. For connection to driver circuitry an opaque metal layer 238 may be deposited over a small portion of the area of the transparent conductor as shown in FIG. 1B.

Contact metals are typically deposited in the via openings after dielectric layer 220 patterning using a physical vapor deposition (PVD) technique such as evaporation or sputtering.

A cathode metal layer 232 is deposited into the opening defined by vias 222, 224 along the sidewalls of the vias 222,224, which are lined with dielectric layer 220. The cathode metal layer 232 may comprise any suitable material known to the skilled artisan. In one or more embodiments, the cathode metal layer 232 is any high reflectivity metal that makes ohmic contact with the n-type layers. In one or more specific embodiments, the cathode metal layer 232 comprises an n-contact material selected from one or more of silver (Ag) and aluminum (Al). In one or more embodiments, the cathode metal layer 232 forms the common cathode

An anode metal layer 234, 236 is deposited into the opening defined by vias 226, 228, respectively, along the sidewalls of the vias 226,228, which are lined with dielectric layer 220. The anode metal layer 234, 236 may comprise any suitable material known to the skilled artisan. In one or more embodiments, the anode metal layer 234, 236 is any high reflectivity metal that makes ohmic contact with the n-type layers. In one or more specific embodiments, the anode metal layer 234, 236 comprises an n-contact material selected from one or more of silver (Ag) and aluminum (Al).

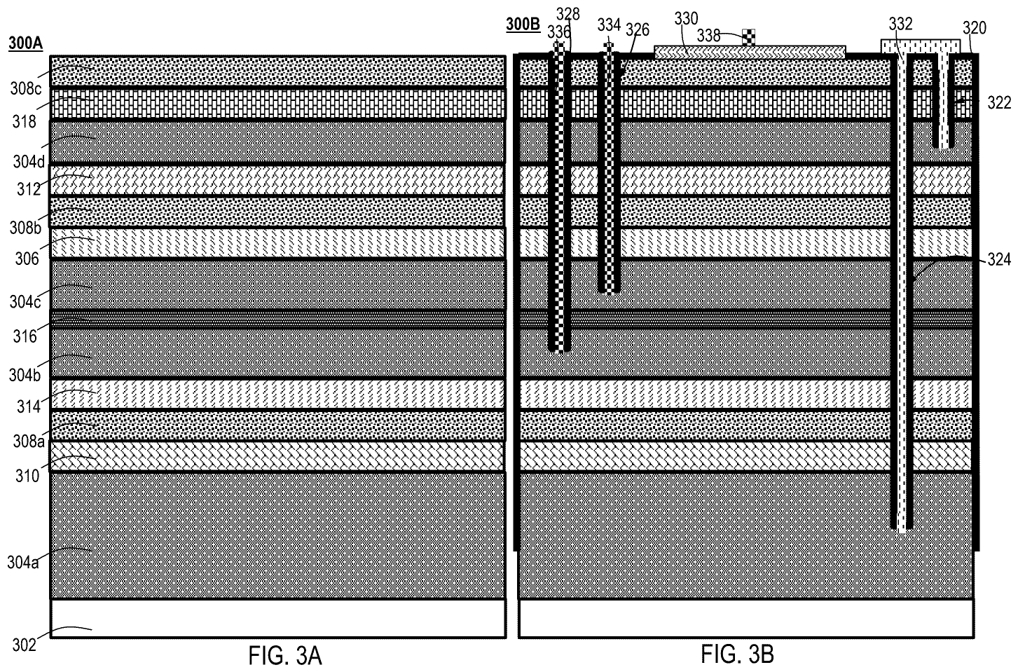

FIG. 3A illustrates a cross-sectional schematic of an epitaxy configuration 300A according to one or more embodiments. FIG. 3B illustrates a cross-section schematic of the epitaxy configuration of FIG. 3A including five terminal polychromatic LEDS according to one or more embodiments.

Referring to FIG. 3A and FIG. 3B, a three-junction polychromatic LED 300B is manufactured by forming an epitaxial stack 300A having three-light emitting active regions. The epitaxial stack 300A includes plurality of III-nitride layers on a substrate 302 to form three p-n junction LEDs on the substrate, one of the p-n junctions having the opposite order of deposition of the n- and p-layers as compared to the others.

According to certain specific embodiments, the first light emitting region of the three-junction polychromatic LED 200A/200B comprises a first n-type layer 304a on the substrate 302.

As described above with respect to FIGS. 1A-1B, in one or more embodiments, a nucleation layer (not illustrated) and dislocation density control layers (not illustrated) may be grown on a suitable substrate 302, such as patterned or non-patterned sapphire. In one or more embodiments, the nucleation layer comprises a III-nitride material. In specific embodiments, the nucleation layer comprises gallium nitride (GaN) or aluminum nitride (AlN).

In one or more embodiments, first n-type layer 304a is grown on the substrate 302, the nucleation layer, and/or the dislocation density control layers. In one or more embodiments, a first n-type layer 304a is formed directly on the substrate 302. The substrate 302 may be any substrate known to one of skill in the art which is configured for use in the formation of LED devices, including those described above with respect to substrate 102.

In one or more embodiments, the first n-type layer 304a, the second n-type layer 304b, the third n-type layer 304c, and the fourth n-type layer 304d, may comprise any Group III-V semiconductors, including binary, ternary, and quaternary alloys of gallium (Ga), aluminum (Al), indium (In), and nitrogen (N), also referred to as III-nitride materials as described above with respect to the n-type layers 104.

In one or more embodiments, the layers of III-nitride material may be deposited by one or more of sputter deposition, atomic layer deposition (ALD), metalorganic chemical vapor deposition (MOCVD), physical vapor deposition (PVD), plasma enhanced atomic layer deposition (PEALD), and plasma enhanced chemical vapor deposition (PECVD), as described above with respect to the n-type layers 104.

In one or more embodiments, μLED stack 300A is manufactured by placing the substrate 302 in a metalorganic vapor-phase epitaxy (MOVPE) reactor so that the μLED array layers are grown epitaxially.

As described above, and as illustrated in FIGS. 3A and 3B, in one or more embodiments, after the growth of the first n-type layer 304a, a first light-emitting active region 310 is formed. In one or more embodiments, the first active region 310 is a blue active region.

In one or more embodiments, the first light-emitting active region 310, and also the second light-emitting active region 312, and the third light-emitting active region 318, includes multiple quantum wells and may include electron blocking layer(s) grown after the quantum wells and strain-control layers grown before the quantum wells. The process of growing the strain-control layers may generate V-pit defects before the growth of the first quantum well. The number of quantum wells typically used for blue LEDs ranges from 1 to 12, the typical barrier thickness ranges from 3 nm to 20 nm, the well thickness ranges from 1 nm to 5 nm, and the well indium concentration ranges from 10% indium to 20% indium. In some embodiments, the active region(s) may be doped with Si or Ge, while in other embodiments, the active region(s) is undoped. In one or more embodiments, the first light-emitting active region 310, the second light-emitting active region 312, and the third light-emitting active region 318 may be comprised of an InGaN quantum well or wells, or layers doped with an optically active transition metal such as GaN:Eu. In one or more embodiments, the active regions 310, 312, 218 are comprised of one or more InGaN quantum wells with GaN or AlGaN barrier layers and usually a progressively higher % indium (In) in the quantum well(s) for blue, green, and red active regions. In some embodiments the quantum wells of different colors may have similar % in but differences in well width and/or barrier layer composition to adjust the emission wavelength.

After growth of the first light-emitting active region 310, a first p-type layer 308a is grown. In one or more embodiments, the first p-type layer 308a, the second p-type layer 308b, and the third p-type layer 308c may independently comprise any Group III-V semiconductors, including binary, ternary, and quaternary alloys of gallium (Ga), aluminum (Al), indium (In), and nitrogen (N), also referred to as III-nitride materials, as described above with respect to the p-type layers 108.

In one or more embodiments, a p/n tunnel junction 314 is grown on the first p-type layer 308a. It is noted that the p/n tunnel junction 214 has layers that are grown in an order that is opposite the layers of the n/p tunnel junction 306. In one or more embodiments, the p/n tunnel junction 314 may be comprised of a heavily doped ((>1e10¹⁹) GaN:Si or GaN:Ge layer grown after a heavily doped GaN:Mg layer, with an optional thin InGaN layer inserted between them. The optional thin InGaN layer may have a graded % in composition.

Still referring to FIG. 3A and FIG. 3B, a second n-type layer 304b is formed on the p/n tunnel junction 314. A current blocking layer 316 is on the second n-type layer 304b. In one or more embodiments, as described above with respect to the current blocking layer 116, the current blocking layer 316 is sandwiched between the second n-type layer 304c and a third n-type layer 304c. In one or more embodiments, a light-emitting junction is on one side of the current blocking layer 316 and a second light-emitting junction having opposite growth order of n- and p-layers is disposed on the opposite side of the current blocking layer 316. In one or more embodiments, in the processed device 300B, two separate contact vias 326, 328 are etched to independently contact each of those two n-type layers.

In one or more embodiments, an n/p tunnel junction 306 is grown on the third n-type layer 304c. In one or more embodiments, the n/p tunnel junction 306 is comprised of heavily doped p-GaN and n-GaN layers with doping concentrations in the range 10¹⁹-10²¹ cm⁻³ and layer thickness typically less than 50 nm. The n/p tunnel junction 306 may also utilize thin InGaN or graded InGaN layers disposed between highly doped GaN layers. In one or more embodiments, the n/p tunnel junction 306 is comprised of a very heavily doped (>1e10²⁰) GaN:Mg layer grown after a very heavily doped GaN:Si or GaN:Ge layer, with an optional thin (<3 nm) AlN or AlGaN layer inserted between them. The optional thin InGaN layer may have a graded % In composition.

Still referring to FIG. 2A and FIG. 2B, a second p-type layer 308b is grown on the n/p tunnel junction 306.

In one or more embodiments, after the second p-type layer 308b is grown, a second light-emitting active region 312 is grown. In one or more embodiments, the second active region 312 is a green active region.

The general range of parameter limits is the same for the second light-emitting active region 312 as for the first light-emitting active region 310, however some differences in specific details may be needed to obtain similar characteristics for the first and second active regions having opposite polarities.

In one or more embodiments, a fourth n-type layer 304d is formed on the second active region 312, followed by the growth of a third light emitting region. The third light emitting region includes a third light-emitting active region 318 is on the fourth n-type layer 304d. In one or more embodiments, the third active region 318 is a red active region. In one or more embodiments, the red active region, in particular, may alternatively be comprised of a GaN layer doped with Eu and optional co-dopants such as O or Mg. Such a layer emits red light via transitions between internal energy levels of the Eu dopants. Alternatively, the red active region may be compromised of InGaN quantum well(s) as described above with suitable design changes to adjust the wavelength.

In one or more embodiments, the epitaxy of the stack 300A ends with growth a third p-type layer 308c on the third active region 318. The Mg doping concentration may be increased near the surface of layer 308c to facilitate ohmic contact formation with metal or transparent conducting oxide electrodes.

As illustrated in FIG. 3B, after epitaxial growth, the epitaxial stack 300A is processed through fabrication steps to form a five terminal, three-junction polychromatic LED device 300B.

In one or more embodiments, four sets of vias 322, 324, 326, and 328 are formed by lithography and dry etching. The vias 322, 324, 326, and 328 have different depths, D1, D2, D3, and D4. In one or more embodiments, the via 322 can have a depth D1 in a range from 0.1 microns to 1.0 microns such that the via 322 terminates in the fourth n-type layer 304d. In one or more embodiments, the via 324 can have a depth D2 in a range from 0.4 microns to 3 microns such that the via 324 terminates in first n-type layer 304a. In one or more embodiments, the via 326 can have a depth D3 in a range from 0.4 microns to 2 microns such that the via 326 terminates in third n-type layer 304c. In one or more embodiments, the via 328 can have a depth D3 in a range from 0.4 microns to 3 microns such that the via 328 terminates in second n-type layer 304b.

The epitaxy stack may then be subjected to an acceptor activation anneal, as described above with respect to the epitaxy stack in FIGS. 1A and 1B.

In one or more embodiments, a dielectric layer 320 is deposited in the vias 322, 324, 326, 328, as described above with respect to dielectric layer 120. In some embodiments, the dielectric layer 320 includes, but is not limited to, oxides (e.g., silicon oxide, aluminum oxide), nitrides (e.g., silicon nitride (SiN)), oxycarbides (e.g., silicon oxycarbide (SiOC)), and oxynitrocarbides (e.g., silicon oxycarbonitride (SiNCO)).

In one or more embodiments, the dielectric layer 320 is patterned using lithography and wet or dry etching to leave openings for metal to contact the semiconductor at desired locations.

In one or more embodiments, a portion of the dielectric layer 320 is removed with dry etching to form an opening where transparent conductive layer 330 is deposited. In one or more embodiments, the transparent conductive layer 330 comprises one or more of indium tin oxide (ITO), zinc oxide (ZnO), or indium zinc oxide (IZO) is deposited by PVD to make electrical contact to the third p-type layer 308c and facilitate current spreading. The transparent conductor layer 330 typically has a thickness between 10 and 200 nm and it optionally may be annealed after deposition to improve its transparency or electrical conductivity. For connection to driver circuitry an opaque metal layer 338 may be deposited over a small portion of the area of the transparent conductor as shown in FIG. 3B.

Contact metals are typically deposited in the via openings after dielectric layer 320 patterning using a physical vapor deposition (PVD) technique such as evaporation or sputtering.

A cathode metal layer 332 is deposited into the opening defined by vias 322, 324 along the sidewalls of the vias 322,324, which are lined with dielectric layer 320. The cathode metal layer 332 may comprise any suitable material known to the skilled artisan. In one or more embodiments, the cathode metal layer 332 is any high reflectivity metal that makes ohmic contact with the n-type layers. In one or more specific embodiments, the cathode metal layer 332 comprises an n-contact material selected from one or more of silver (Ag) and aluminum (Al). In one or more embodiments, the cathode metal layer 332 forms the common cathode.

An anode metal layer 334, 336 is deposited into the opening defined by vias 326, 328, respectively, along the sidewalls of the vias 326, 328, which are lined with dielectric layer 320. The anode metal layer 334, 336 may comprise any suitable material known to the skilled artisan. In one or more embodiments, the anode metal layer 334, 336 is any high reflectivity metal that makes ohmic contact with the n-type layers. In one or more specific embodiments, the anode metal layer 334, 336 comprises an n-contact material selected from one or more of silver (Ag) and aluminum (Al).

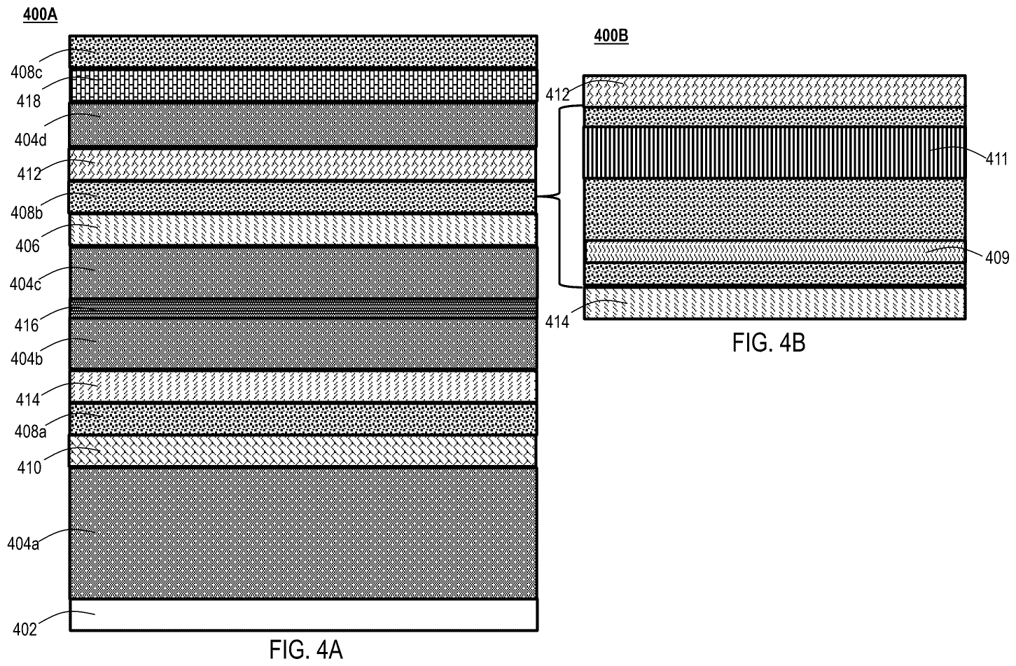

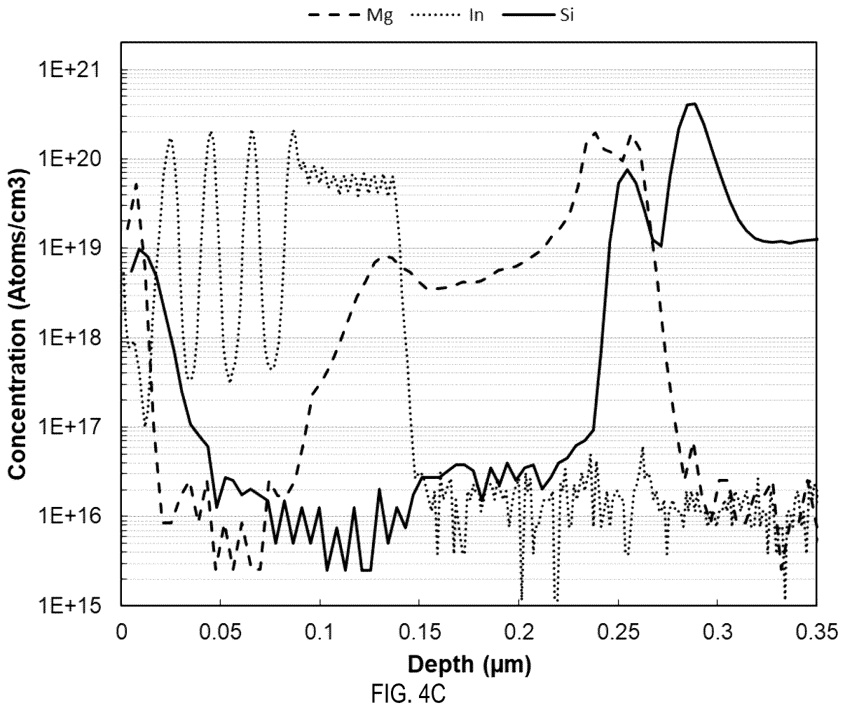

FIG. 4A illustrates a cross-sectional schematic of an epitaxy configuration 400A according to one or more embodiments. FIG. 4B illustrates an enlarged cross-section schematic of a portion 400B of the epitaxy configuration of FIG. 4A according to one or more embodiments.

The epitaxial stack 400A includes a plurality of III-nitride layers on a substrate 402 to form three p-n junction LEDs on the substrate, one of the p-n junctions having the opposite order of deposition of the n- and p-layers as compared to the others.

According to certain specific embodiments, the first light emitting region of the three-junction polychromatic LED 400A comprises a first n-type layer 404a on the substrate 402.

As described above with respect to FIGS. 1A-1B, in one or more embodiments, a nucleation layer (not illustrated) and dislocation density control layers (not illustrated) may be grown on a suitable substrate 402, such as patterned or non-patterned sapphire. In one or more embodiments, the nucleation layer comprises a III-nitride material. In specific embodiments, the nucleation layer comprises gallium nitride (GaN) or aluminum nitride (AlN).

In one or more embodiments, first n-type layer 404a is grown on the substrate 402, the nucleation layer, and/or the dislocation density control layers. In one or more embodiments, a first n-type layer 404a is formed directly on the substrate 402. The substrate 402 may be any substrate known to one of skill in the art which is configured for use in the formation of LED devices, including those described above with respect to substrate 102.

In one or more embodiments, the first n-type layer 404a, the second n-type layer 404b, the third n-type layer 404c, and the fourth n-type layer 404d, may comprise any Group III-V semiconductors, including binary, ternary, and quaternary alloys of gallium (Ga), aluminum (Al), indium (In), and nitrogen (N), also referred to as III-nitride materials as described above with respect to the n-type layers 104.

In one or more embodiments, the layers of III-nitride material may be deposited by one or more of sputter deposition, atomic layer deposition (ALD), metalorganic chemical vapor deposition (MOCVD), physical vapor deposition (PVD), plasma enhanced atomic layer deposition (PEALD), and plasma enhanced chemical vapor deposition (PECVD), as described above with respect to the n-type layers 404.

In one or more embodiments, μLED stack 400A is manufactured by placing the substrate 402 in a metalorganic vapor-phase epitaxy (MOVPE) reactor so that the μLED array layers are grown epitaxially.

As described above, and as illustrated in FIG. 4A, in one or more embodiments, after the growth of the first n-type layer 404a, a first light-emitting active region 410 is formed. In one or more embodiments, the first active region 410 is a blue active region.

In one or more embodiments, the first light-emitting active region 410, and also the second light-emitting active region 412, and the third light-emitting active region 418, includes multiple quantum wells and may include electron blocking layer(s) grown after the quantum wells and strain-control layers grown before the quantum wells. The process of growing the strain-control layers may generate V-pit defects before the growth of the first quantum well. The number of quantum wells typically used for blue LEDs ranges from 1 to 12, the typical barrier thickness ranges from 3 nm to 20 nm, the well thickness ranges from 1 nm to 5 nm, and the well indium concentration ranges from 10% indium to 20% indium. In some embodiments, the active region(s) may be doped with Si or Ge, while in other embodiments, the active region(s) is undoped. In one or more embodiments, the first light-emitting active region 410, the second light-emitting active region 412, and the third light-emitting active region 418 may be comprised of an InGaN quantum well or wells, or layers doped with an optically active transition metal such as GaN:Eu. In one or more embodiments, the active regions 410, 412, 418 are comprised of one or more InGaN quantum wells with GaN or AlGaN barrier layers and a progressively higher % indium (In) in the quantum well(s) for blue, green, and red active regions. In some embodiments the quantum wells of different colors may have similar % in but differences in well width and/or barrier layer composition to adjust the emission wavelength.

After growth of the first light-emitting active region 410, a first p-type layer 408a is grown. In one or more embodiments, the first p-type layer 408a, the second p-type layer 408b, and the third p-type layer 408c may independently comprise any Group III-V semiconductors, including binary, ternary, and quaternary alloys of gallium (Ga), aluminum (Al), indium (In), and nitrogen (N), also referred to as III-nitride materials, as described above with respect to the p-type layers 108.

In one or more embodiments, a p/n tunnel junction 414 is grown on the first p-type layer 308a. It is noted that the p/n tunnel junction 414 has layers that are grown in an order that is opposite the layers of the n/p tunnel junction 406. In one or more embodiments, the p/n tunnel junction 414 may be comprised of a heavily doped ((>1e10¹⁹) GaN:Si or GaN:Ge layer grown after a heavily doped GaN:Mg layer, with an optional thin InGaN layer inserted between them. The optional thin InGaN layer may have a graded % in composition.

Still referring to FIG. 4A, a second n-type layer 404b is formed on the p/n tunnel junction 414. A current blocking layer 416 is on the second n-type layer 404b. In one or more embodiments, as described above with respect to the current blocking layer 116, the current blocking layer 416 is sandwiched between the second n-type layer 404b and a third n-type layer 404c. In one or more embodiments, a light-emitting junction is on one side of the current blocking layer 416 and a second light-emitting junction having opposite growth order of n- and p-layers is disposed on the opposite side of the current blocking layer 416. In one or more embodiments, in the processed device (not illustrated), two separate contact vias may be etched to independently contact each of those two n-type layers.

In one or more embodiments, an n/p tunnel junction 406 is grown on the third n-type layer 404c. In one or more embodiments, the n/p tunnel junction 406 is comprised of heavily doped p-GaN and n-GaN layers with doping concentrations in the range 10¹⁹-10²¹ cm⁻³ and layer thickness typically less than 50 nm. The n/p tunnel junction 406 may also utilize thin InGaN or graded InGaN layers disposed between highly doped GaN layers. In one or more embodiments, the n/p tunnel junction 406 is comprised of a very heavily doped (>1e10²⁰) GaN:Mg layer grown after a very heavily doped GaN:Si or GaN:Ge layer, with an optional thin (<3 nm) AlN or AlGaN layer inserted between them.

Still referring to FIG. 4A, a second p-type layer 408b is grown on the n/p tunnel junction 406. In one or more embodiments, as illustrated in FIG. 4B, the second p-type layer 408b includes additional layers 400B which are called “diffusion blocking layers”. As used herein, the term “diffusion blocking layers” refers to layers which are grown for the purpose of hindering detrimental diffusion of point defects and impurities in the direction perpendicular to the substrate wafer plane during growth or post-growth annealing steps. Referring to FIG. 4B, the diffusion blocking layers 400B may be incorporated in the second p-type layer 408b which are grown immediately after the n/p tunnel junction 406.

In one or more embodiments, the diffusion blocking layers 400B may be comprised of a short-period superlattice of semiconductor alloy layers 411 having different lattice constants, such as, but not limited to, GaN and InGaN or AlGaN, or layers 409 co-doped with Mg and Si but having overall p-type conductivity due to a higher concentration of Mg versus Si.

Without intending to be bound by theory, one strategy for impurity blocking is to grow a short-period superlattice 411 of epitaxial layers with different lattice constants (for example, InGaN and GaN or GaN and AlGaN). The superlattice 411 may have between 5 and 40 repeating units. The superlattice period, i.e., combined thickness of the two layers that are repeated, is typically 5 nm to 10 nm. The indium concentration of InGaN layers in a short-period superlattice 411 is typically smaller than used in quantum wells (<10% for the superlattice 411). Another strategy is to grow a single GaN layer 409 co-doped with Si and Mg, having Si concentration greater than 5e18 cm⁻³ but with p-type conductivity due to a larger concentration of Mg versus Si. The co-doped layer 409 typically has a thickness of between 5 nm and 50 nm. Without intending to be bound by theory, it is believed that the repeated variations in the crystal strain field over short distances (a few atomic layers) within the impurity blocking layers 400B can explain their effectiveness in impeding diffusion of Mg through them. The strain field varies due to alloy composition in a short-period superlattice and varies due to dopant clustering in co-doped layers. The two strategies for impurity blocking layers may be both used together in the same implementation, as illustrated in FIG. 4B. In other unillustrated embodiments, each strategy may be used on its own.

As illustrated in FIG. 4C, the effectiveness of the approach at mitigating Mg diffusion is shown with experimental data (secondary ion mass spectrometry), corresponding to an LED wafer with p-type layers grown before the quantum wells. In FIG. 4C, the Mg concentration in the quantum well closest to the p-type layer is below 3e16 cm⁻³ making possible high IQE.

In one or more embodiments, after the second p-type layer 408b is grown, a second light-emitting active region 412 is grown. In one or more embodiments, the second active region 412 is a green active region.

The general range of parameter limits is the same for the second light-emitting active region 412 as for the first light-emitting active region 410, however some differences in specific details may be needed to obtain similar characteristics for the first and second active regions having opposite polarities.

In one or more embodiments, a fourth n-type layer 404d is formed on the second active region 412, followed by the growth of a third light emitting region. The third light emitting region includes a third light-emitting active region 418 is on the fourth n-type layer 404d. In one or more embodiments, the third active region 418 is a red active region. In one or more embodiments, the red active region, in particular, may alternatively be comprised of a GaN layer doped with Eu and optional co-dopants such as O or Mg. Such a layer emits red light via transitions between internal energy levels of the Eu dopants. Alternatively, the red active region may be compromised of InGaN quantum well(s) as described above with suitable design changes to adjust the wavelength.

In one or more embodiments, the epitaxy of the stack 400A is ended with growth a third p-type layer 408c on the third active region 418. The Mg doping concentration may be increased near the surface of layer 408c to facilitate ohmic contact formation with metal or transparent conducting oxide electrodes.

After epitaxial growth, the epitaxial stack 400A is processed through fabrication steps to form a five terminal, three-junction polychromatic LED device, such as that illustrated in FIG. 3B.

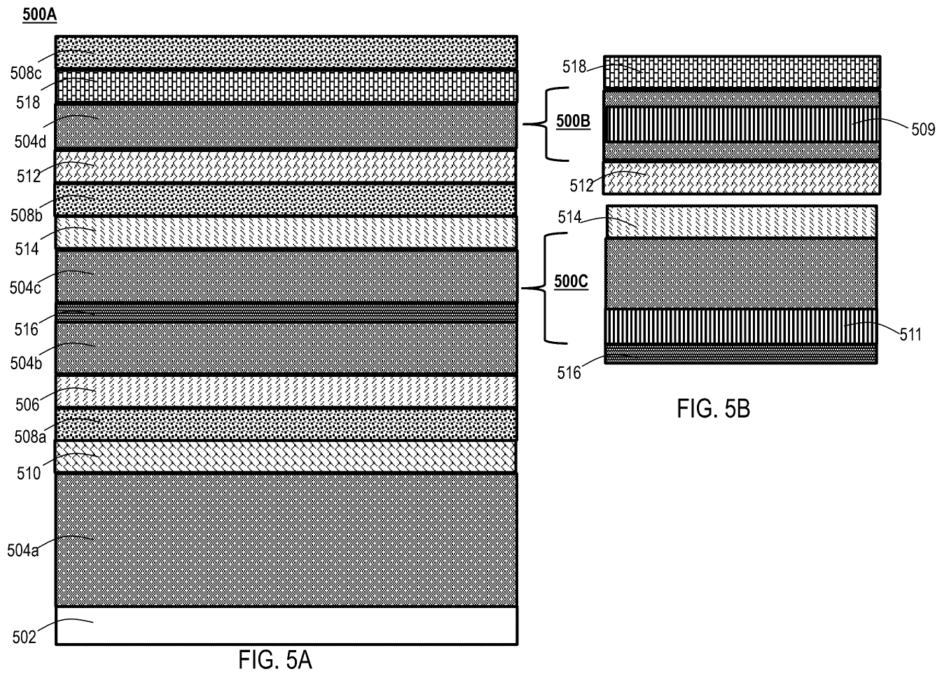

FIG. 5A illustrates a cross-sectional schematic of an epitaxy configuration 500A according to one or more embodiments. FIG. 5B illustrates an enlarged cross-section schematic of a portion 500B of the epitaxy configuration of FIG. 5A according to one or more embodiments.

The epitaxial stack 500A includes a plurality of III-nitride layers on a substrate 502 to form three p-n junction LEDs on the substrate, one of the p-n junctions having the opposite order of deposition of the n- and p-layers as compared to the others.

According to certain specific embodiments, the first light emitting region of the three-junction polychromatic LED 500A comprises a first n-type layer 504a on the substrate 502.

As described above with respect to FIGS. 1A-1B, in one or more embodiments, a nucleation layer (not illustrated) and dislocation density control layers (not illustrated) may be grown on a suitable substrate 502, such as patterned or non-patterned sapphire. In one or more embodiments, the nucleation layer comprises a III-nitride material. In specific embodiments, the nucleation layer comprises gallium nitride (GaN) or aluminum nitride (AlN).

In one or more embodiments, first n-type layer 504a is grown on the substrate 502, the nucleation layer, and/or the dislocation density control layers. In one or more embodiments, a first n-type layer 404a is formed directly on the substrate 502. The substrate 502 may be any substrate known to one of skill in the art which is configured for use in the formation of LED devices, including those described above with respect to substrate 102.

In one or more embodiments, the first n-type layer 504a, the second n-type layer 504b, the third n-type layer 504c, and the fourth n-type layer 504d, may comprise any Group III-V semiconductors, including binary, ternary, and quaternary alloys of gallium (Ga), aluminum (Al), indium (In), and nitrogen (N), also referred to as III-nitride materials as described above with respect to the n-type layers 104.

In one or more embodiments, the layers of III-nitride material may be deposited by one or more of sputter deposition, atomic layer deposition (ALD), metalorganic chemical vapor deposition (MOCVD), physical vapor deposition (PVD), plasma enhanced atomic layer deposition (PEALD), and plasma enhanced chemical vapor deposition (PECVD), as described above with respect to the n-type layers 504.

In one or more embodiments, μLED stack 400A is manufactured by placing the substrate 502 in a metalorganic vapor-phase epitaxy (MOVPE) reactor so that the μLED array layers are grown epitaxially.

As described above, and as illustrated in FIG. 5A, in one or more embodiments, after the growth of the first n-type layer 504a, a first light-emitting active region 510 is formed. In one or more embodiments, the first active region 510 is a blue active region.

In one or more embodiments, the first light-emitting active region 510, and also the second light-emitting active region 512, and the third light-emitting active region 518, includes multiple quantum wells and may include electron blocking layer(s) grown after the quantum wells and strain-control layers grown before the quantum wells. The process of growing the strain-control layers may generate V-pit defects before the growth of the first quantum well. The number of quantum wells typically used for blue LEDs ranges from 1 to 12, the typical barrier thickness ranges from 2 nm to 20 nm, the well thickness ranges from 1 nm to 5 nm, and the well indium concentration ranges from 10% indium to 20% indium. In some embodiments, the active region(s) may be doped with Si or Ge, while in other embodiments, the active region(s) is undoped. In one or more embodiments, the first light-emitting active region 510, the second light-emitting active region 512, and the third light-emitting active region 518 may be comprised of an InGaN quantum well or wells, or layers doped with an optically active transition metal such as GaN:Eu. In one or more embodiments, the active regions 510, 512, 518 are comprised of one or more InGaN quantum wells with GaN or AlGaN barrier layers and usually a progressively higher % indium (In) in the quantum well(s) for blue, green, and red active regions. In some embodiments the quantum wells of different colors may have similar % in but differences in well width and/or barrier layer composition to adjust the emission wavelength.

After growth of the first light-emitting active region 510, a first p-type layer 508a is grown. In one or more embodiments, the first p-type layer 508a, the second p-type layer 508b, and the third p-type layer 508c may independently comprise any Group III-V semiconductors, including binary, ternary, and quaternary alloys of gallium (Ga), aluminum (Al), indium (In), and nitrogen (N), also referred to as III-nitride materials, as described above with respect to the p-type layers 108.

In one or more embodiments, a p/n tunnel junction 514 is grown on the first p-type layer 508a. It is noted that the p/n tunnel junction 514 has layers that are grown in an order that is opposite the layers of the n/p tunnel junction 506. In one or more embodiments, the p/n tunnel junction 514 may be comprised of a heavily doped ((>1e10¹⁹) GaN:Si or GaN:Ge layer grown after a heavily doped GaN:Mg layer, with an optional thin InGaN layer inserted between them. The optional thin InGaN layer may have a graded % in composition.

Still referring to FIG. 5A, a second n-type layer 504b is formed on the p/n tunnel junction 514. A current blocking layer 516 is on the second n-type layer 504b. In one or more embodiments, as described above with respect to the current blocking layer 116, the current blocking layer 516 is sandwiched between the second n-type layer 504b and a third n-type layer 504c. In one or more embodiments, a light-emitting junction is on one side of the current blocking layer 516 and a second light-emitting junction having opposite growth order of n- and p-layers is disposed on the opposite side of the current blocking layer 516. In one or more embodiments, in the processed device (not illustrated), two separate contact vias may be etched to independently contact each of those two n-type layers.

In one or more embodiments, an n/p tunnel junction 506 is grown on the third n-type layer 504c. In one or more embodiments, the n/p tunnel junction 506 is comprised of heavily doped p-GaN and n-GaN layers with doping concentrations in the range 10¹⁹-10²¹ cm⁻³ and layer thickness typically less than 50 nm. The n/p tunnel junction 406 may also utilize thin InGaN or graded InGaN layers disposed between highly doped GaN layers. In one or more embodiments, the n/p tunnel junction 506 is comprised of a very heavily doped (>1e10²⁰) GaN:Mg layer grown after a very heavily doped GaN:Si or GaN:Ge layer, with an optional thin (<3 nm) AlN or AlGaN layer inserted between them.

Still referring to FIG. 5A, a second p-type layer 508b is grown on the n/p tunnel junction 506.

In one or more embodiments, after the second p-type layer 508b is grown, a second light-emitting active region 512 is grown. In one or more embodiments, the second active region 512 is a green active region.

The general range of parameter limits is the same for the second light-emitting active region 512 as for the first light-emitting active region 510, however some differences in specific details may be needed to obtain similar characteristics for the first and second active regions having opposite polarities.

In one or more embodiments, a fourth n-type layer 504d is formed on the second active region 512, followed by the growth of a third light emitting region. The third light emitting region includes a third light-emitting active region 518 is on the fourth n-type layer 504d. In one or more embodiments, the third active region 518 is a red active region. In one or more embodiments, the red active region, in particular, may alternatively be comprised of a GaN layer doped with Eu and optional co-dopants such as O or Mg. Such a layer emits red light via transitions between internal energy levels of the Eu dopants.

In one or more embodiments, the epitaxy of the stack 500A is ended with growth a third p-type layer 508c on the third active region 518. The Mg doping concentration may be increased near the surface of layer 508c to facilitate ohmic contact formation with metal or transparent conducting oxide electrodes.

After epitaxial growth, the epitaxial stack 500A is processed through fabrication steps to form a five terminal, three-junction polychromatic LED device, such as that illustrated in FIG. 3B.

In one or more embodiments, diffusion blocking layers, as described above with respect to FIG. 4A and FIG. 4B, may be incorporated into the epitaxial stack 500A. In one or more embodiments, it may also be advantageous to insert diffusion blocking layers 500B and/or 5000 into n-type layers as illustrated in FIG. 5B.

For example, when the current blocking layer 516 is a GaN:Mg p-type layer, Mg can diffuse into the subsequently grown third n-type layer 504c and decrease its conductivity by compensating donor dopants. Placing a short period superlattice 511 after the GaN:Mg current blocking layer 516 avoids contaminating the third n-type layer 504c with Mg.

In other embodiments, it may be advantageous to incorporate diffusion blocking layers 500B between the second light-emitting active region 512 and the third light-emitting active region 518. In one or more embodiments, an n-type InGaN/GaN superlattice 509 is incorporated in n-GaN layer 504d between red and green active regions 512, 518.

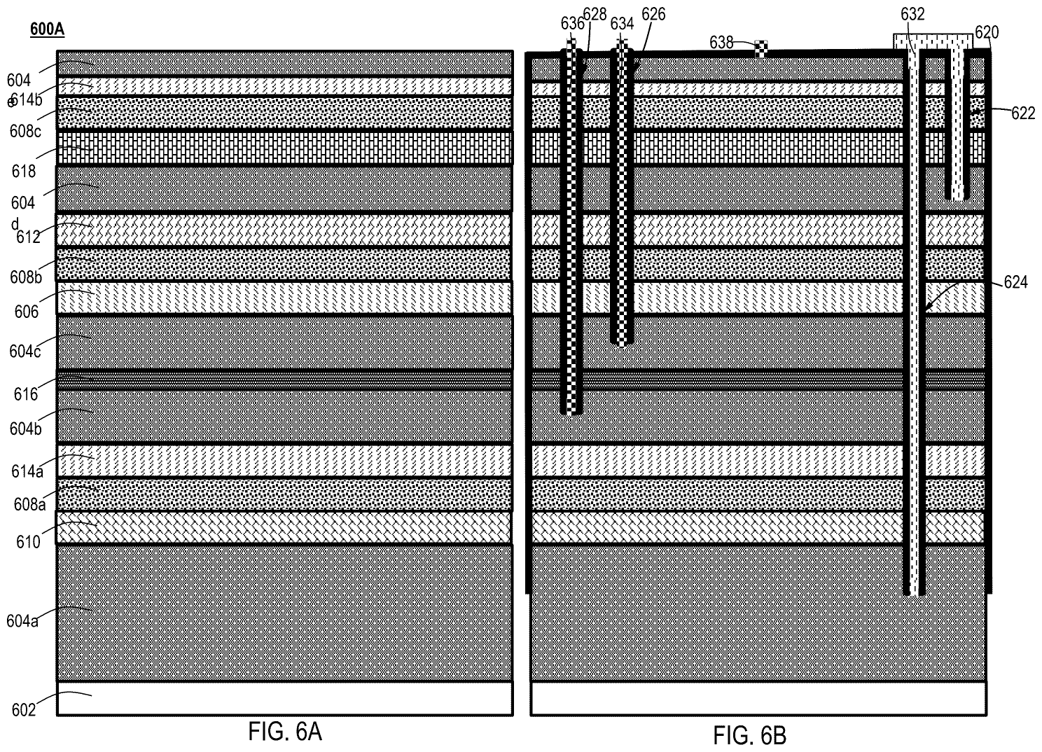

As illustrated in FIGS. 6A and 6B, it may be advantageous to incorporate three tunnel junctions into the epitaxy stack. In one or more embodiments, a third (p/n) tunnel junction may be included in the epitaxy wafer, allowing all of the electrical contacts to be made to n-type layers.

FIG. 6A illustrates a cross-sectional schematic of an epitaxy configuration 600A according to one or more embodiments. FIG. 6B illustrates a cross-section schematic of the epitaxy configuration of FIG. 6A including five terminal polychromatic LEDS according to one or more embodiments.

Referring to FIG. 6A and FIG. 6B, a three-junction polychromatic LED 600B is manufactured by forming an epitaxial stack 600A having three-light emitting active regions. The epitaxial stack 600A includes plurality of III-nitride layers on a substrate 602 to form three p-n junction LEDs on the substrate, one of the p-n junctions having the opposite order of deposition of the n- and p-layers as compared to the others.

According to certain specific embodiments, the first light emitting region of the three-junction polychromatic LED 600A/600B comprises a first n-type layer 604a on the substrate 602.

As described above with respect to FIGS. 1A-1B, in one or more embodiments, a nucleation layer (not illustrated) and dislocation density control layers (not illustrated) may be grown on a suitable substrate 602, such as patterned or non-patterned sapphire. In one or more embodiments, the nucleation layer comprises a III-nitride material. In specific embodiments, the nucleation layer comprises gallium nitride (GaN) or aluminum nitride (AlN).

In one or more embodiments, the first n-type layer 604a is grown on the substrate 602, the nucleation layer, and/or the dislocation density control layers. In one or more embodiments, a first n-type layer 604a is formed directly on the substrate 602. The substrate 602 may be any substrate known to one of skill in the art which is configured for use in the formation of LED devices, including those described above with respect to substrate 102.

In one or more embodiments, the first n-type layer 604a, the second n-type layer 604b, the third n-type layer 604c, the fourth n-type layer 604d, and the fifth n-type layer 605e may comprise any Group III-V semiconductors, including binary, ternary, and quaternary alloys of gallium (Ga), aluminum (Al), indium (In), and nitrogen (N), also referred to as III-nitride materials as described above with respect to the n-type layers 104.

In one or more embodiments, the layers of III-nitride material may be deposited by one or more of sputter deposition, atomic layer deposition (ALD), metalorganic chemical vapor deposition (MOCVD), physical vapor deposition (PVD), plasma enhanced atomic layer deposition (PEALD), and plasma enhanced chemical vapor deposition (PECVD), as described above with respect to the n-type layers 104.

In one or more embodiments, μLED stack 600A is manufactured by placing the substrate 602 in a metalorganic vapor-phase epitaxy (MOVPE) reactor so that the μLED array layers are grown epitaxially.

As described above, and as illustrated in FIGS. 6A and 6B, in one or more embodiments, after the growth of the first n-type layer 604a, a first light-emitting active region 610 is formed. In one or more embodiments, the first active region 610 is a blue active region.

In one or more embodiments, the first light-emitting active region 610, and also the second light-emitting active region 612, and the third light-emitting active region 618, includes multiple quantum wells and may include electron blocking layer(s) grown after the quantum wells and strain-control layers grown before the quantum wells. The process of growing the strain-control layers may generate V-pit defects before the growth of the first quantum well. The number of quantum wells typically used for blue LEDs ranges from 1 to 12, the typical barrier thickness ranges from 3 nm to 20 nm, the well thickness ranges from 1 nm to 5 nm, and the well indium concentration ranges from 10% indium to 20% indium. In some embodiments, the active region(s) may be doped with Si or Ge, while in other embodiments, the active region(s) is undoped. In one or more embodiments, the first light-emitting active region 610, the second light-emitting active region 612, and the third light-emitting active region 618 may be comprised of an InGaN quantum well or wells, or layers doped with an optically active transition metal such as GaN:Eu. In one or more embodiments, the active regions 610, 612, 618 are comprised of one or more InGaN quantum wells with GaN or AlGaN barrier layers and usually a progressively higher % indium (In) in the quantum well(s) for blue, green, and red active regions. In some embodiments the quantum wells of different colors may have similar % in but differences in well width and/or barrier layer composition to adjust the emission wavelength.

After growth of the first light-emitting active region 610, a first p-type layer 608a is grown. In one or more embodiments, the first p-type layer 608a, the second p-type layer 608b, and the third p-type layer 608c may independently comprise any Group III-V semiconductors, including binary, ternary, and quaternary alloys of gallium (Ga), aluminum (Al), indium (In), and nitrogen (N), also referred to as III-nitride materials, as described above with respect to the p-type layers 108.

In one or more embodiments, a first p/n tunnel junction 614a is grown on the first p-type layer 508a. It is noted that the first p/n tunnel junction 614a and the second p/n tunnel junction 614b have layers that are grown in an order that is opposite the layers of the n/p tunnel junction 606. In one or more embodiments, the first p/n tunnel junction 614a and the second p/n tunnel junction 614b may be comprised of a heavily doped ((>1e10¹⁹) GaN:Si or GaN:Ge layer grown after a heavily doped GaN:Mg layer, with an optional thin InGaN layer inserted between them. The optional thin InGaN layer may have a graded % in composition.

Still referring to FIG. 6A, a second n-type layer 604b is formed on the first p/n tunnel junction 614a. A current blocking layer 616 is on the second n-type layer 604b. In one or more embodiments, as described above with respect to the current blocking layer 116, the current blocking layer 616 is sandwiched between the second n-type layer 604b and a third n-type layer 604c. In one or more embodiments, a light-emitting junction is on one side of the current blocking layer 616 and a second light-emitting junction having opposite growth order of n- and p-layers is disposed on the opposite side of the current blocking layer 616. In one or more embodiments, in the processed device as illustrated in FIG. 6B, two separate contact vias 626, 628 may be etched to independently contact each of those two n-type layers.

In one or more embodiments, an n/p tunnel junction 606 is grown on the third n-type layer 604c. In one or more embodiments, the n/p tunnel junction 606 is comprised of heavily doped p-GaN and n-GaN layers with doping concentrations in the range 10¹⁹-10²¹ cm⁻³ and layer thickness typically less than 50 nm. The n/p tunnel junction 606 may also utilize thin InGaN or graded InGaN layers disposed between highly doped GaN layers. In one or more embodiments, the n/p tunnel junction 606 is comprised of a very heavily doped (>1e10²⁰) GaN:Mg layer grown after a very heavily doped GaN:Si or GaN:Ge layer, with an optional thin (<3 nm) AlN or AlGaN layer inserted between them.

Still referring to FIG. 6A, a second p-type layer 608b is grown on the n/p tunnel junction 606.

In one or more embodiments, after the second p-type layer 608b is grown, a second light-emitting active region 612 is grown. In one or more embodiments, the second active region 612 is a green active region.

The general range of parameter limits is the same for the second light-emitting active region 612 as for the first light-emitting active region 610, however some differences in specific details may be needed to obtain similar characteristics for the first and second active regions having opposite polarities.

In one or more embodiments, a fourth n-type layer 604d is formed on the second active region 612, followed by the growth of a third light emitting region. The third light emitting region includes a third light-emitting active region 618 on the fourth n-type layer 604d. In one or more embodiments, the third active region 618 is a red active region. In one or more embodiments, the red active region, in particular, may alternatively be comprised of a GaN layer doped with Eu and optional co-dopants such as O or Mg. Such a layer emits red light via transitions between internal energy levels of the Eu dopants. Alternatively, the red active region may be compromised of InGaN quantum well(s) as described above with suitable design changes to adjust the wavelength.

In one or more embodiments, a third p-type layer 608c is then grown on the third active region 618. A second p/n tunnel junction 614b is formed on the third-type layer, and the epitaxy of the stack 600A is ended with growth of a fifth n-type layer 604e on the second p/n tunnel junction 614b.

As illustrated in FIG. 6B, after epitaxial growth, the epitaxial stack 600A is processed through fabrication steps to form a five terminal, three-junction polychromatic LED device 600B.

In one or more embodiments, four sets of vias 622, 624, 626, and 628 are formed by lithography and dry etching. The vias 622, 624, 626, and 628 have different depths, D1, D2, D3, and D4. In one or more embodiments, the via 622 can have a depth D1 in a range from 0.1 microns to 1.0 microns such that the via 622 terminates in the fourth n-type layer 604d. In one or more embodiments, the via 624 can have a depth D2 in a range from 0.4 microns to 3 microns such that the via 624 terminates in first n-type layer 604a. In one or more embodiments, the via 626 can have a depth D3 in a range from 0.4 microns to 2 microns such that the via 626 terminates in third n-type layer 604c. In one or more embodiments, the via 628 can have a depth D3 in a range from 0.4 microns to 3 microns such that the via 628 terminates in second n-type layer 604b.

The epitaxy stack may then be subjected to an acceptor activation anneal, as described above with respect to the epitaxy stack in FIGS. 1A and 1B.

In one or more embodiments, a dielectric layer 620 is deposited in the vias 622, 624, 626, 628, as described above with respect to dielectric layer 120. In some embodiments, the dielectric layer 620 includes, but is not limited to, oxides (e.g., silicon oxide, aluminum oxide), nitrides (e.g., silicon nitride (SiN)), oxycarbides (e.g., silicon oxycarbide (SiOC)), and oxynitrocarbides (e.g., silicon oxycarbonitride (SiNCO)).

In one or more embodiments, the dielectric layer 620 is patterned using lithography and wet or dry etching to leave openings for metal to contact the semiconductor at desired locations. For connection to driver circuitry an opaque metal layer 638 may be deposited over a small portion of the area of the transparent conductor as shown in FIG. 6B.

Contact metals are typically deposited in the via openings after dielectric layer 620 patterning using a physical vapor deposition (PVD) technique such as evaporation or sputtering.

A cathode metal layer 632 is deposited into the opening defined by vias 622, 624 along the sidewalls of the vias 622, 624, which are lined with dielectric layer 620. The cathode metal layer 632 may comprise any suitable material known to the skilled artisan. In one or more embodiments, the cathode metal layer 632 is any high reflectivity metal that makes ohmic contact with the n-type layers. In one or more specific embodiments, the cathode metal layer 632 comprises an n-contact material selected from one or more of silver (Ag) and aluminum (Al). In one or more embodiments, the cathode metal layer 632 forms the common cathode.

An anode metal layer 634, 636 is deposited into the opening defined by vias 626, 628, respectively, along the sidewalls of the vias 626, 628, which are lined with dielectric layer 620. The anode metal layer 634, 636 may comprise any suitable material known to the skilled artisan. In one or more embodiments, the anode metal layer 634, 636 is any high reflectivity metal that makes ohmic contact with the n-type layers. In one or more specific embodiments, the anode metal layer 634, 636 comprises an n-contact material selected from one or more of silver (Ag) and aluminum (Al).

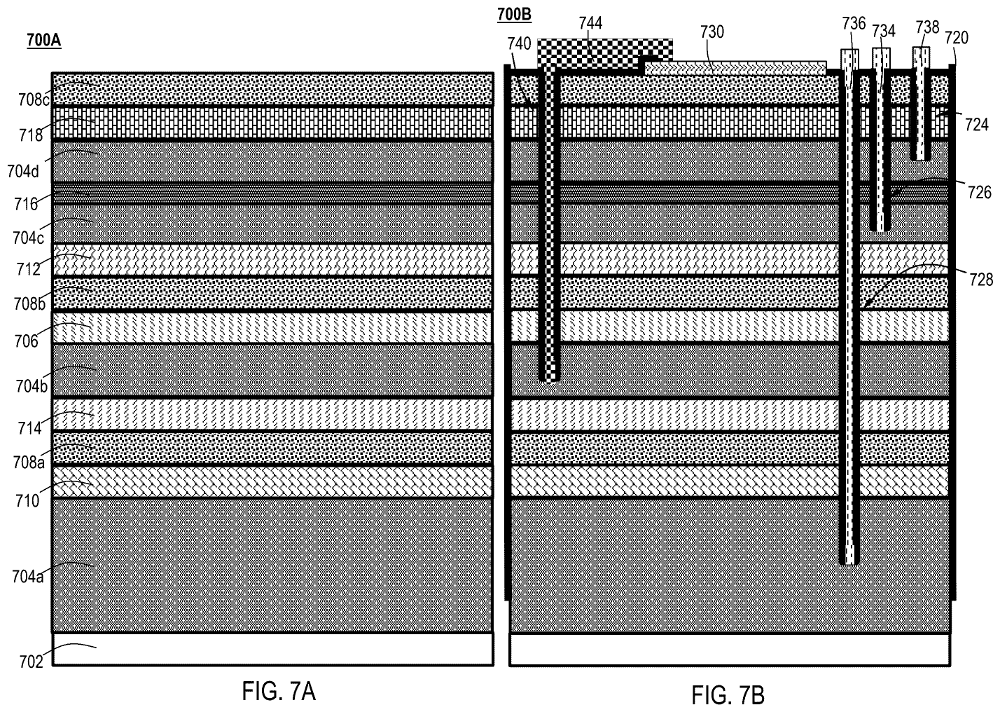

As illustrated in FIGS. 7A and 7B, it may be advantageous to incorporate a common anode into the device 700B.

FIG. 7A illustrates a cross-sectional schematic of an epitaxy configuration 700A according to one or more embodiments. FIG. 7B illustrates a cross-section schematic of the epitaxy configuration of FIG. 7A including five terminal polychromatic LEDS according to one or more embodiments.

Referring to FIG. 7A and FIG. 7B, a three-junction polychromatic LED 700B is manufactured by forming an epitaxial stack 700A having three-light emitting active regions. The epitaxial stack 700A includes plurality of III-nitride layers on a substrate 702 to form three p-n junction LEDs on the substrate, one of the p-n junctions having the opposite order of deposition of the n- and p-layers as compared to the others.

According to certain specific embodiments, the first light emitting region of the three-junction polychromatic LED 700A/700B comprises a first n-type layer 704a on the substrate 702.

As described above with respect to FIGS. 1A-1B, in one or more embodiments, a nucleation layer (not illustrated) and dislocation density control layers (not illustrated) may be grown on a suitable substrate 702, such as patterned or non-patterned sapphire. In one or more embodiments, the nucleation layer comprises a III-nitride material. In specific embodiments, the nucleation layer comprises gallium nitride (GaN) or aluminum nitride (AlN).

In one or more embodiments, first n-type layer 704a is grown on the substrate 702, the nucleation layer, and/or the dislocation density control layers. In one or more embodiments, a first n-type layer 704a is formed directly on the substrate 702. The substrate 702 may be any substrate known to one of skill in the art which is configured for use in the formation of LED devices, including those described above with respect to substrate 102.

In one or more embodiments, the first n-type layer 704a, the second n-type layer 704b, the third n-type layer 704c, and the fourth n-type layer 704d may comprise any Group III-V semiconductors, including binary, ternary, and quaternary alloys of gallium (Ga), aluminum (Al), indium (In), and nitrogen (N), also referred to as III-nitride materials as described above with respect to the n-type layers 104.

In one or more embodiments, the layers of III-nitride material may be deposited by one or more of sputter deposition, atomic layer deposition (ALD), metalorganic chemical vapor deposition (MOCVD), physical vapor deposition (PVD), plasma enhanced atomic layer deposition (PEALD), and plasma enhanced chemical vapor deposition (PECVD), as described above with respect to the n-type layers 104.

In one or more embodiments, μLED stack 700A is manufactured by placing the substrate 702 in a metalorganic vapor-phase epitaxy (MOVPE) reactor so that the μLED array layers are grown epitaxially.

As described above, and as illustrated in FIGS. 7A and 7B, in one or more embodiments, after the growth of the first n-type layer 704a, a first light-emitting active region 710 is formed. In one or more embodiments, the first active region 710 is a blue active region.

In one or more embodiments, the first light-emitting active region 710, and also the second light-emitting active region 712, and the third light-emitting active region 718, includes multiple quantum wells and may include electron blocking layer(s) grown after the quantum wells and strain-control layers grown before the quantum wells. The process of growing the strain-control layers may generate V-pit defects before the growth of the first quantum well. The number of quantum wells typically used for blue LEDs ranges from 1 to 12, the typical barrier thickness ranges from 3 nm to 20 nm, the well thickness ranges from 1 nm to 5 nm, and the well indium concentration ranges from 10% indium to 20% indium. In some embodiments, the active region(s) may be doped with Si or Ge, while in other embodiments, the active region(s) is undoped. In one or more embodiments, the first light-emitting active region 710, the second light-emitting active region 712, and the third light-emitting active region 718 may be comprised of an InGaN quantum well or wells, or layers doped with an optically active transition metal such as GaN:Eu. In one or more embodiments, the active regions 710, 712, 718 are comprised of one or more InGaN quantum wells with GaN or AlGaN barrier layers and a progressively higher % indium (In) in the quantum well(s) for blue, green, and red active regions. In some embodiments the quantum wells of different colors may have similar % In but differences in well width and/or barrier layer composition to adjust the emission wavelength.

After growth of the first light-emitting active region 710, a first p-type layer 708a is grown. In one or more embodiments, the first p-type layer 708a, the second p-type layer 708b, and the third p-type layer 708c may independently comprise any Group III-V semiconductors, including binary, ternary, and quaternary alloys of gallium (Ga), aluminum (Al), indium (In), and nitrogen (N), also referred to as III-nitride materials, as described above with respect to the p-type layers 108.

In one or more embodiments, a p/n tunnel junction 714 is grown on the first p-type layer 708a. It is noted that the p/n tunnel junction 714 has layers that are grown in an order that is opposite the layers of the n/p tunnel junction 706. In one or more embodiments, the p/n tunnel junction 714a and the second p/n tunnel junction 714b may be comprised of a heavily doped ((>1e10¹⁹) GaN:Si or GaN:Ge layer grown after a heavily doped GaN:Mg layer, with an optional thin InGaN layer inserted between them. The optional thin InGaN layer may have a graded % in composition.

Still referring to FIG. 7A, a second n-type layer 704b is formed on the p/n tunnel junction 714. In one or more embodiments, an n/p tunnel junction 706 is grown on the second n-type layer 704b. In one or more embodiments, the n/p tunnel junction 706 is comprised of heavily doped p-GaN and n-GaN layers with doping concentrations in the range 10¹⁹-10²¹ cm⁻³ and layer thickness typically less than 50 nm. The n/p tunnel junction 706 may also utilize thin InGaN or graded InGaN layers disposed between highly doped GaN layers. In one or more embodiments, the n/p tunnel junction 706 is comprised of a very heavily doped (>1e10²⁰) GaN:Mg layer grown after a very heavily doped GaN:Si or GaN:Ge layer, with an optional thin (<3 nm) AlN or AlGaN layer inserted between them.

Still referring to FIG. 7A, a second p-type layer 708b is grown on the n/p tunnel junction 706.

In one or more embodiments, after the second p-type layer 708b is grown, a second light-emitting active region 712 is grown. In one or more embodiments, the second active region 712 is a green active region.

The general range of parameter limits is the same for the second light-emitting active region 712 as for the first light-emitting active region 710, however some differences in specific details may be needed to obtain similar characteristics for the first and second active regions having opposite polarities.

Still referring to FIG. 7A, a third n-type layer 704c is formed on the second light-emitting active region 712. A current blocking layer 716 is on the third n-type layer 704c.

In one or more embodiments, as described above with respect to the current blocking layer 116, the current blocking layer 716 is sandwiched between the third n-type layer 704c and a fourth n-type layer 704d. In one or more embodiments, a light-emitting junction is on one side of the current blocking layer 716 and a second light-emitting junction having opposite growth order of n- and p-layers is disposed on the opposite side of the current blocking layer 716. In one or more embodiments, in the processed device as illustrated in FIG. 7B, two separate contact vias 724, 726 may be etched to independently contact each of those two n-type layers.

In one or more embodiments, a third light emitting region is grown. The third light emitting region includes a third light-emitting active region 718 is on the fourth n-type layer 704d. In one or more embodiments, the third active region 718 is a red active region. In one or more embodiments, the red active region, in particular, may alternatively be comprised of a GaN layer doped with Eu and optional co-dopants such as O or Mg. Such a layer emits red light via transitions between internal energy levels of the Eu dopants.

In one or more embodiments, the epitaxy of the stack 700A is ended with growth of a third p-type layer 708c

As illustrated in FIG. 7B, after epitaxial growth, the epitaxial stack 700A is processed through fabrication steps to form a five terminal, three-junction polychromatic LED device 700B.

In one or more embodiments, four sets of vias 724, 726, 728, and 740 are formed by lithography and dry etching. The vias 724, 726, 728, and 740 have different depths, D1, D2, D3, and D4. In one or more embodiments, the via 724 can have a depth D1 in a range from 0.1 microns to 1.0 microns such that the via 724 terminates in the fourth n-type layer 704d. In one or more embodiments, the via 726 can have a depth D2 in a range from 0.4 microns to 3 microns such that the via 726 terminates in third n-type layer 704c. In one or more embodiments, the via 728 can have a depth D3 in a range from 0.4 microns to 2 microns such that the via 728 terminates in first n-type layer 704a. In one or more embodiments, the via 740 can have a depth D3 in a range from 0.4 microns to 3 microns such that the via 740 terminates in second n-type layer 704b.

The epitaxy stack may then be subjected to an acceptor activation anneal, as described above with respect to the epitaxy stack in FIGS. 1A and 1B.

In one or more embodiments, a dielectric layer 720 is deposited in the vias 724, 726, 728, and 740, as described above with respect to dielectric layer 120. In some embodiments, the dielectric layer 720 includes, but is not limited to, oxides (e.g., silicon oxide, aluminum oxide), nitrides (e.g., silicon nitride (SiN)), oxycarbides (e.g., silicon oxycarbide (SiOC)), and oxynitrocarbides (e.g., silicon oxycarbonitride (SiNCO)).

In one or more embodiments, the dielectric layer 720 is patterned using lithography and wet or dry etching to leave openings for metal to contact the semiconductor at desired locations. In one or more embodiments, a portion of the dielectric layer 720 is removed with dry etching to form an opening where transparent conductive layer 730 is deposited. In one or more embodiments, the transparent conductive layer 730 comprises one or more of indium tin oxide (ITO), zinc oxide (ZnO), or indium zinc oxide (IZO) is deposited by PVD to make electrical contact to the third p-type layer 708c and facilitate current spreading. The transparent conductor layer 730 typically has a thickness between 10 and 200 nm and it optionally may be annealed after deposition to improve its transparency or electrical conductivity.

Contact metals are typically deposited in the via openings after dielectric layer 620 patterning using a physical vapor deposition (PVD) technique such as evaporation or sputtering.

A cathode metal layer 734, 736, 738 is deposited into the opening defined by vias 724, 726, and 728 along the sidewalls of the vias 724, 726, and 728, which are lined with dielectric layer 720. The cathode metal layer 734, 736, 738 may comprise any suitable material known to the skilled artisan. In one or more embodiments, the cathode metal layer 734, 736, 738 is any high reflectivity metal that makes ohmic contact with the n-type layers. In one or more specific embodiments, the cathode metal layer 734, 736, 738 comprises an n-contact material selected from one or more of silver (Ag) and aluminum (Al).

In one or more embodiments, an anode metal layer 744 is deposited in a contact opening 740 along the sidewalls of the via 740. The anode metal layer 744 may comprise any suitable material known to the skilled artisan. In one or more embodiments, the anode metal layer 744 is any high reflectivity metal that makes ohmic contact with the n-type layers. In some embodiments, the anode metal layer 740 and the cathode metal layer 734, 736, 738 comprise the same material and are deposited in the same step and are patterned using a technique such as lift-off or dry etching. In one or more specific embodiments, the anode metal layer 744 comprises an n-contact material selected from one or more of silver (Ag) and aluminum (Al). In some embodiments, the anode metal layer 744 forms a common anode.

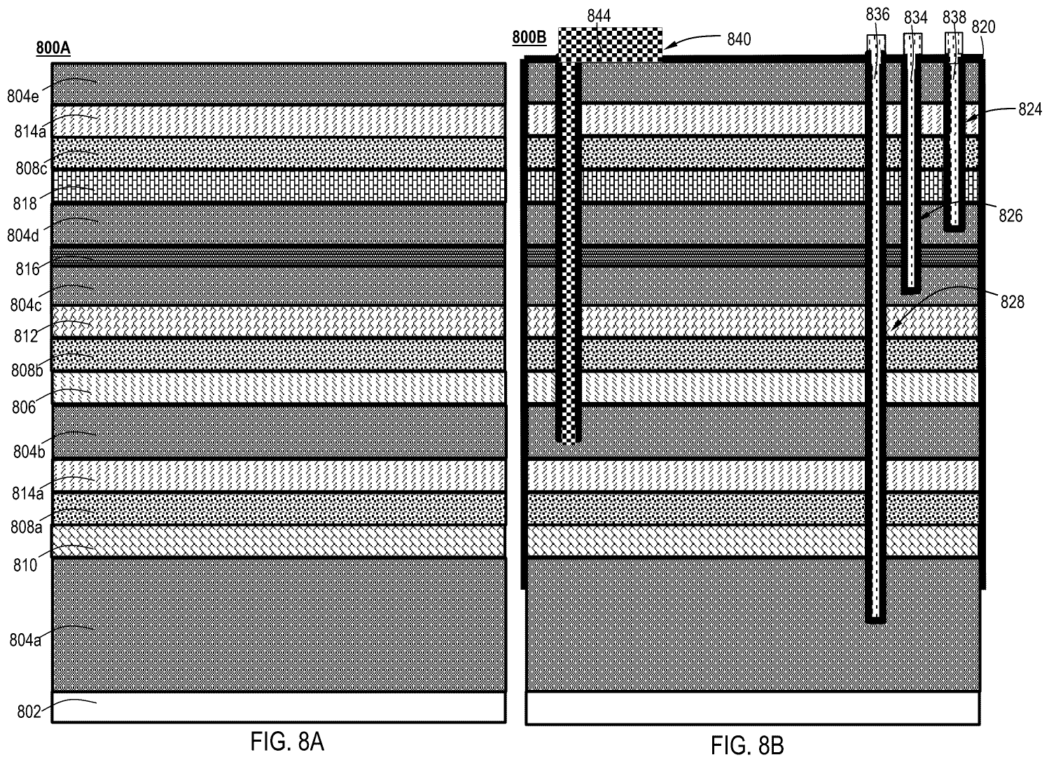

As illustrated in FIGS. 8A and 8B, it may be advantageous to incorporate a common anode into the device 800B. Additionally, in one or more embodiments, it may be advantageous to incorporate three tunnel junctions into the epitaxy stack. In one or more embodiments, a third (p/n) tunnel junction may be included in the epitaxy wafer, allowing all of the electrical contacts to be made to n-type layers.

FIG. 8A illustrates a cross-sectional schematic of an epitaxy configuration 800A according to one or more embodiments. FIG. 8B illustrates a cross-section schematic of the epitaxy configuration of FIG. 8A including five terminal polychromatic LEDS according to one or more embodiments.

Referring to FIG. 8A and FIG. 8B, a three-junction polychromatic LED 800B is manufactured by forming an epitaxial stack 800A having three-light emitting active regions. The epitaxial stack 800A includes plurality of III-nitride layers on a substrate 802 to form three p-n junction LEDs on the substrate, one of the p-n junctions having the opposite order of deposition of the n- and p-layers as compared to the others.

According to certain specific embodiments, the first light emitting region of the three-junction polychromatic LED 800A/800B comprises a first n-type layer 804a on the substrate 802.

As described above with respect to FIGS. 1A-1B, in one or more embodiments, a nucleation layer (not illustrated) and dislocation density control layers (not illustrated) may be grown on a suitable substrate 802, such as patterned or non-patterned sapphire. In one or more embodiments, the nucleation layer comprises a III-nitride material. In specific embodiments, the nucleation layer comprises gallium nitride (GaN) or aluminum nitride (AlN).

In one or more embodiments, first n-type layer 804a is grown on the substrate 802, the nucleation layer, and/or the dislocation density control layers. In one or more embodiments, a first n-type layer 804a is formed directly on the substrate 802. The substrate 802 may be any substrate known to one of skill in the art which is configured for use in the formation of LED devices, including those described above with respect to substrate 102.

In one or more embodiments, the first n-type layer 804a, the second n-type layer 804b, the third n-type layer 804c, the fourth n-type layer 804d, and the fifth n-type layer 804e may comprise any Group III-V semiconductors, including binary, ternary, and quaternary alloys of gallium (Ga), aluminum (Al), indium (In), and nitrogen (N), also referred to as III-nitride materials as described above with respect to the n-type layers 104.

In one or more embodiments, the layers of III-nitride material may be deposited by one or more of sputter deposition, atomic layer deposition (ALD), metalorganic chemical vapor deposition (MOCVD), physical vapor deposition (PVD), plasma enhanced atomic layer deposition (PEALD), and plasma enhanced chemical vapor deposition (PECVD), as described above with respect to the n-type layers 104.

In one or more embodiments, μLED stack 800A is manufactured by placing the substrate 802 in a metalorganic vapor-phase epitaxy (MOVPE) reactor so that the μLED array layers are grown epitaxially.

As described above, and as illustrated in FIGS. 8A and 8B, in one or more embodiments, after the growth of the first n-type layer 804a, a first light-emitting active region 810 is formed. In one or more embodiments, the first active region 810 is a blue active region.

In one or more embodiments, the first light-emitting active region 810, and also the second light-emitting active region 812, and the third light-emitting active region 818, includes multiple quantum wells and may include electron blocking layer(s) grown after the quantum wells and strain-control layers grown before the quantum wells. The process of growing the strain-control layers may generate V-pit defects before the growth of the first quantum well. The number of quantum wells typically used for blue LEDs ranges from 1 to 12, the typical barrier thickness ranges from 3 nm to 20 nm, the well thickness ranges from 1 nm to 5 nm, and the well indium concentration ranges from 10% indium to 20% indium. In some embodiments, the active region(s) may be doped with Si or Ge, while in other embodiments, the active region(s) is undoped. In one or more embodiments, the first light-emitting active region 810, the second light-emitting active region 812, and the third light-emitting active region 818 may be comprised of an InGaN quantum well or wells, or layers doped with an optically active transition metal such as GaN:Eu. In one or more embodiments, the active regions 810, 812, 818 are comprised of one or more InGaN quantum wells with GaN or AlGaN barrier layers and a progressively higher % indium (In) in the quantum well(s) for blue, green, and red active regions. In some embodiments the quantum wells of different colors may have similar % in but differences in well width and/or barrier layer composition to adjust the emission wavelength.

After growth of the first light-emitting active region 810, a first p-type layer 808a is grown. In one or more embodiments, the first p-type layer 808a, the second p-type layer 808b, and the third p-type layer 808c may independently comprise any Group III-V semiconductors, including binary, ternary, and quaternary alloys of gallium (Ga), aluminum (Al), indium (In), and nitrogen (N), also referred to as III-nitride materials, as described above with respect to the p-type layers 108.

In one or more embodiments, a first p/n tunnel junction 814a is grown on the first p-type layer 808a. It is noted that the first p/n tunnel junction 814a and the second p/n tunnel junction 814b have layers that are grown in an order that is opposite the layers of the n/p tunnel junction 806. In one or more embodiments, the first p/n tunnel junction 814a and the second p/n tunnel junction 814b may be comprised of a heavily doped ((>1e10¹⁹) GaN:Si or GaN:Ge layer grown after a heavily doped GaN:Mg layer, with an optional thin InGaN layer inserted between them. The optional thin InGaN layer may have a graded % in composition.

Still referring to FIG. 8A, a second n-type layer 804b is formed on the p/n tunnel junction 814. In one or more embodiments, an n/p tunnel junction 806 is grown on the second n-type layer 804b. In one or more embodiments, the n/p tunnel junction 806 is comprised of heavily doped p-GaN and n-GaN layers with doping concentrations in the range 10¹⁹-10²¹ cm⁻³ and layer thickness typically less than 50 nm. The n/p tunnel junction 806 may also utilize thin InGaN or graded InGaN layers disposed between highly doped GaN layers. In one or more embodiments, the n/p tunnel junction 806 is comprised of a very heavily doped (>1e10²⁰) GaN:Mg layer grown after a very heavily doped GaN:Si or GaN:Ge layer, with an optional thin (<3 nm) AlN or AlGaN layer inserted between them.

Still referring to FIG. 8A, a second p-type layer 808b is grown on the n/p tunnel junction 806.

In one or more embodiments, after the second p-type layer 808b is grown, a second light-emitting active region 812 is grown. In one or more embodiments, the second active region 812 is a green active region.

The general range of parameter limits is the same for the second light-emitting active region 812 as for the first light-emitting active region 810, however some differences in specific details may be needed to obtain similar characteristics for the first and second active regions having opposite polarities.

Still referring to FIG. 8A, a third n-type layer 804c is formed on the second light-emitting active region 812. A current blocking layer 816 is on the third n-type layer 804c. In one or more embodiments, as described above with respect to the current blocking layer 116, the current blocking layer 816 is sandwiched between the third n-type layer 804c and a fourth n-type layer 804d. In one or more embodiments, a light-emitting junction is on one side of the current blocking layer 816 and a second light-emitting junction having opposite growth order of n- and p-layers is disposed on the opposite side of the current blocking layer 816. In one or more embodiments, in the processed device as illustrated in FIG. 8B, two separate contact vias 824, 826 may be etched to independently contact each of those two n-type layers.

In one or more embodiments, a third light emitting region is grown. The third light emitting region includes a third light-emitting active region 818 on the fourth n-type layer 804d. In one or more embodiments, the third active region 818 is a red active region. In one or more embodiments, the red active region, in particular, may alternatively be comprised of a GaN layer doped with Eu and optional co-dopants such as O or Mg. Such a layer emits red light via transitions between internal energy levels of the Eu dopants.

In one or more embodiments, a third p-type layer 808c is then grown on the third active region 818. A second p/n tunnel junction 814b is formed on the third p-type layer 808c, and the epitaxy of the stack 800A is ended with growth of a fifth n-type layer 804e on the second p/n tunnel junction 814b.

As illustrated in FIG. 8B, after epitaxial growth, the epitaxial stack 800A is processed through fabrication steps to form a five terminal, three-junction polychromatic LED device 800B.

In one or more embodiments, four sets of vias 824, 826, 828, and 840 are formed by lithography and dry etching. The vias 824, 826, 828, and 840 have different depths, D1, D2, D3, and D4. In one or more embodiments, the via 824 can have a depth D1 in a range from 0.1 microns to 1.0 microns such that the via 824 terminates in the n-type layer 804d. In one or more embodiments, the via 826 can have a depth D2 in a range from 0.4 microns to 3 microns such that the via 826 terminates in third n-type layer 804c. In one or more embodiments, the via 828 can have a depth D3 in a range from 0.4 microns to 2 microns such that the via 828 terminates in first n-type layer 804a. In one or more embodiments, the via 840 can have a depth D3 in a range from 0.4 microns to 3 microns such that the via 840 terminates in second n-type layer 804b.

The epitaxy stack may then be subjected to an acceptor activation anneal, as described above with respect to the epitaxy stack in FIGS. 1A and 1B.

In one or more embodiments, a dielectric layer 820 is deposited in the vias 824, 826, 828, and 840, as described above with respect to dielectric layer 120. In some embodiments, the dielectric layer 820 includes, but is not limited to, oxides (e.g., silicon oxide, aluminum oxide), nitrides (e.g., silicon nitride (SiN)), oxycarbides (e.g., silicon oxycarbide (SiOC)), and oxynitrocarbides (e.g., silicon oxycarbonitride (SiNCO)).

In one or more embodiments, the dielectric layer 820 is patterned using lithography and wet or dry etching to leave openings for metal to contact the semiconductor at desired locations.

Contact metals are typically deposited in the via openings after dielectric layer 820 patterning using a physical vapor deposition (PVD) technique such as evaporation or sputtering.

A cathode metal layer 834, 836, 838 is deposited into the opening defined by vias 824, 826, and 828 along the sidewalls of the vias 824, 826, and 828, which are lined with dielectric layer 820. The cathode metal layer 834, 836, 838 may comprise any suitable material known to the skilled artisan. In one or more embodiments, the cathode metal layer 834, 836, 838 is any high reflectivity metal that makes ohmic contact with the n-type layers. In one or more specific embodiments, the cathode metal layer 834, 836, 838 comprises an n-contact material selected from one or more of silver (Ag) and aluminum (Al).

In one or more embodiments, an anode metal layer 844 is deposited in a contact opening along the sidewalls of the via 840. The anode metal layer 844 may comprise any suitable material known to the skilled artisan. In one or more embodiments, the anode metal layer 844 is any high reflectivity metal that makes ohmic contact with the n-type layers. In some embodiments, the anode metal layer 840 and the cathode metal layer 834, 836, 838 comprise the same material and are deposited in the same step and are patterned using a technique such as lift-off or dry etching. In one or more specific embodiments, the anode metal layer 844 comprises an n-contact material selected from one or more of silver (Ag) and aluminum (Al). In some embodiments, the anode metal layer 844 forms a common anode.

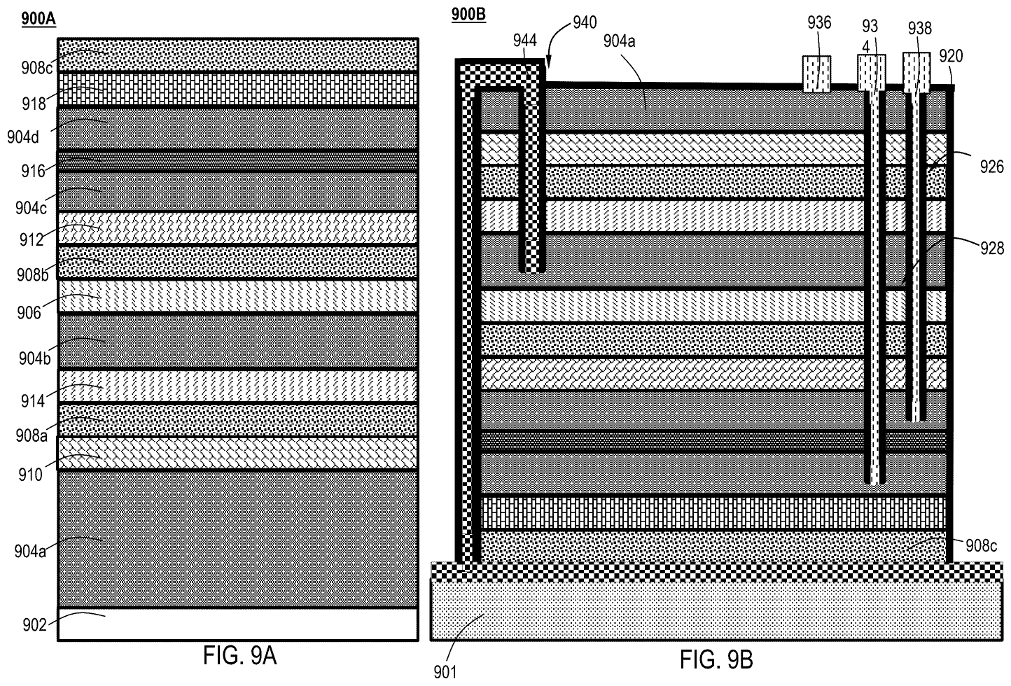

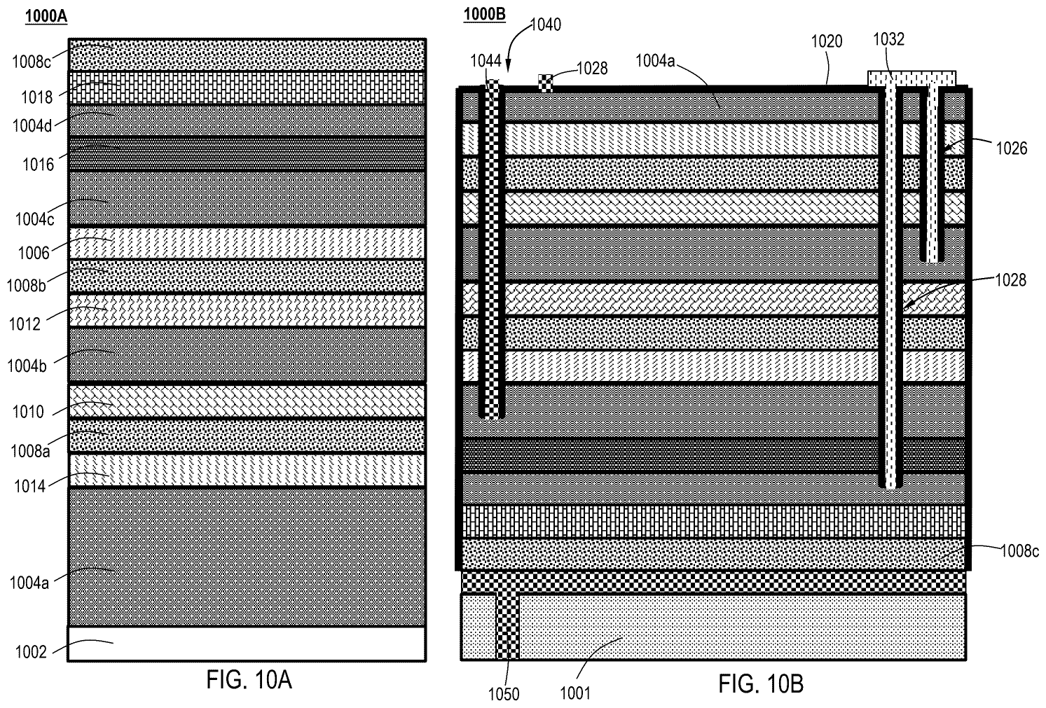

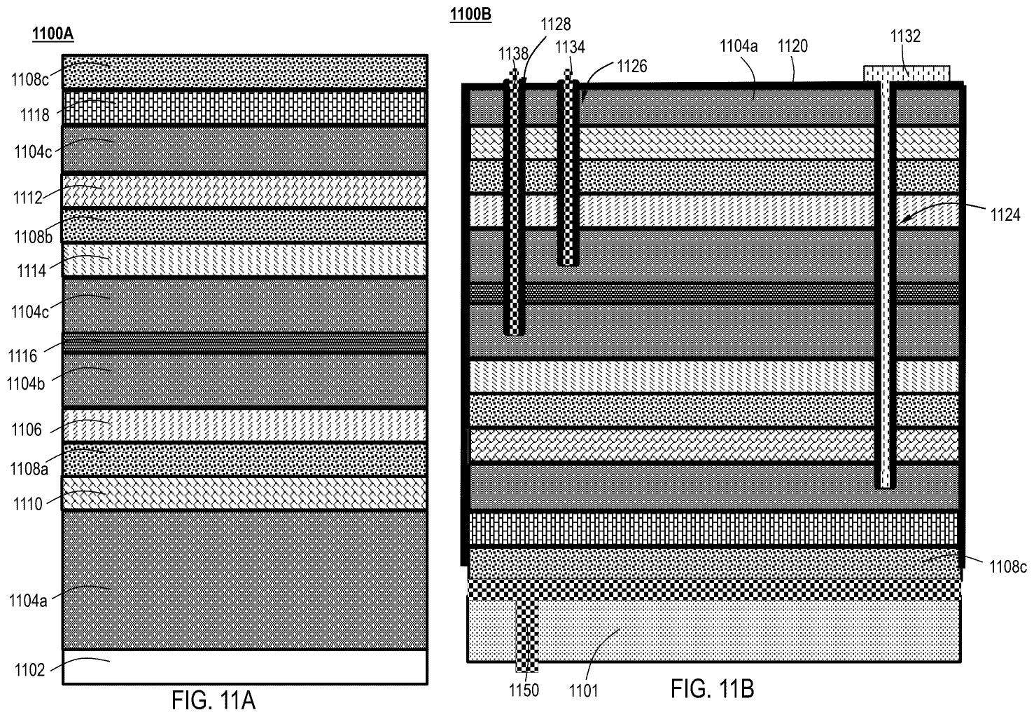

As illustrated in FIGS. 9A-9B, FIGS. 10A-10B, and in FIGS. 11A-11B, in a further different set of embodiments, the final epitaxial layer grown is a p-type layer 908c, 1008c, 1108c, and a sequence of metals is deposited on the entire surface of this layer. This sequence of metals may comprise a first material such as Ag, Pt, Pd, Ni, or a transparent conductive oxide (e.g., ITO), which makes a low resistance electrical contact to the p-type layer 908c, 1008c, 1108c, followed by another metal layer with high optical reflectivity, refractory metal layer(s) which impede metal interdiffusion, and low melting point metal layers which are suitable for wafer-to-wafer bonding.

The grown epitaxial wafer 900A, 1000A, 1100A is then placed in physical contact with a sub-mount wafer 901, 1001, 1101, which has been suitably prepared for wafer bonding. The grown epitaxial wafer 900A, 1000A, 1100A is bonded to the sub-mount wafer 901, 1001, 1101 by application of heat and pressure. After wafer bonding, the growth substrate 902, 1002, 1102 is removed using a process such as laser lift-off, which is applicable to sapphire growth substrates, or grinding and etching, which is applicable to silicon growth substrates. Contact vias 926, 928, 940, 1026, 1028, 1040, 1124, 1126, 1128 are then processed from the side of the epitaxy that was originally adjacent to the growth substrate, using one or more of the methods described above. One of the contacts 934, 936, 938, 944, 1028, 1032, 1044, 1132, 1134, 1138 may be connected to driver circuitry through the sub-mount wafer, as shown.

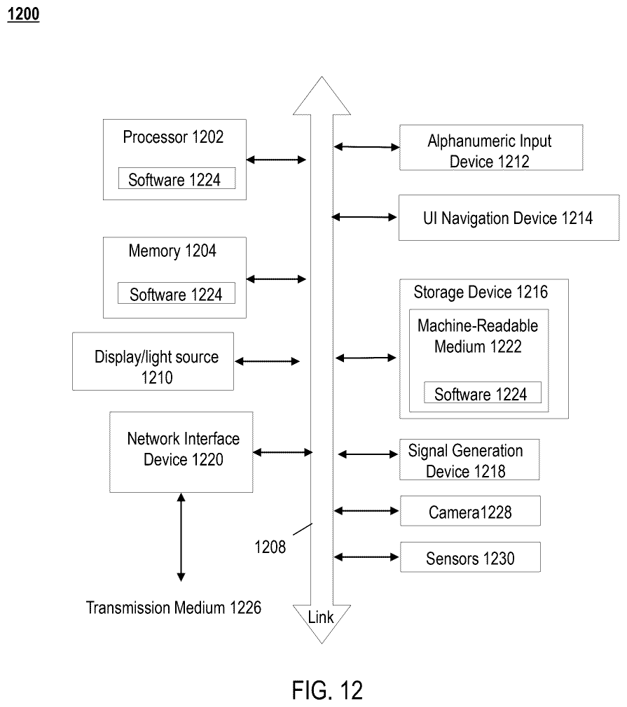

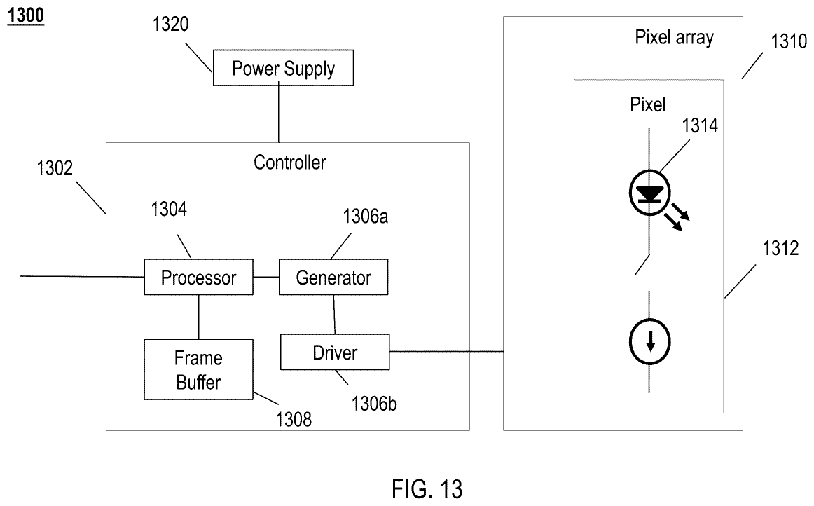

FIG. 12 illustrates an example of a general device in accordance with some embodiments. The device 1200 may be a mobile device such as a laptop computer (PC), a tablet PC, a smart phone, or an augmented reality (AR)/virtual reality (VR), or an automotive device, for example. Various elements may be provided on the backplane indicated above, while other elements may be local or remote. Examples, as described herein, may include, or may operate on, logic or a number of components, modules, or mechanisms.

Modules and components are tangible entities (e.g., hardware) capable of performing specified operations and may be configured or arranged in a certain manner. In an example, circuits may be arranged (e.g., internally or with respect to external entities such as other circuits) in a specified manner as a module. In an example, the whole or part of one or more computer systems (e.g., a standalone, client or server computer system) or one or more hardware processors may be configured by firmware or software (e.g., instructions, an application portion, or an application) as a module that operates to perform specified operations. In an example, the software may reside on a machine readable medium. In an example, the software, when executed by the underlying hardware of the module, causes the hardware to perform the specified operations.

Accordingly, the term “module” (and “component”) is understood to encompass a tangible entity, be that an entity that is physically constructed, specifically configured (e.g., hardwired), or temporarily (e.g., transitorily) configured (e.g., programmed) to operate in a specified manner or to perform part or all of any operation described herein. Considering examples in which modules are temporarily configured, each of the modules need not be instantiated at any one moment in time. For example, where the modules comprise a general-purpose hardware processor configured using software, the general-purpose hardware processor may be configured as respective different modules at different times. Software may accordingly configure a hardware processor, for example, to constitute a particular module at one instance of time and to constitute a different module at a different instance of time.

The electronic device 1200 may include a hardware processor (or equivalently processing circuitry) 1202 (e.g., a central processing unit (CPU), a GPU, a hardware processor core, or any combination thereof), a memory 1204 (which may include main and static memory), some or all of which may communicate with each other via an interlink (e.g., bus) 1208. The memory 1204 may contain any or all of removable storage and non-removable storage, volatile memory, or non-volatile memory. The electronic device 1200 may further include a display/light source 1210 such as the LEDs described above, or a video display, an alphanumeric input device 1212 (e.g., a keyboard), and a user interface (UI) navigation device 1214 (e.g., a mouse). In an example, the display/light source 1210, input device 1212 and UI navigation device 1214 may be a touch screen display. The electronic device 1200 may additionally include a storage device (e.g., drive unit) 1216, a signal generation device 1218 (e.g., a speaker), a network interface device 1220, one or more cameras 1228, and one or more sensors 1230, such as a global positioning system (GPS) sensor, compass, accelerometer, or other sensor such as those described herein. The electronic device 1200 may further include an output controller, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The storage device 1216 may include a non-transitory machine readable medium 1222 (hereinafter simply referred to as machine readable medium) on which is stored one or more sets of data structures or instructions 1224 (e.g., software) embodying or utilized by any one or more of the techniques or functions described herein. The instructions 1224 may also reside, completely or at least partially, within the memory 1204 and/or within the hardware processor 1202 during execution thereof by the electronic device 1200. While the machine readable medium 1222 is illustrated as a single medium, the term “machine readable medium” may include a single medium or multiple media (e.g., a centralized or distributed database, and/or associated caches and servers) configured to store the one or more instructions 1224.

The term “machine readable medium” may include any medium that is capable of storing, encoding, or carrying instructions for execution by the electronic device 1200 and that cause the electronic device 1200 to perform any one or more of the techniques of the present disclosure, or that is capable of storing, encoding or carrying data structures used by or associated with such instructions. Non-limiting machine-readable medium examples may include solid-state memories, and optical and magnetic media. Specific examples of machine-readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; Random Access Memory (RAM); and CD-ROM and DVD-ROM disks.

The instructions 1224 may further be transmitted or received over a communications network using a transmission medium 1226 via the network interface device 1220 utilizing any one of a number of wireless local area network (WLAN) transfer protocols or a SPI or CAN bus. Example communication networks may include a local area network (LAN), a wide area network (WAN), a packet data network (e.g., the Internet), mobile telephone networks (e.g., cellular networks), Plain Old Telephone (POTS) networks, and wireless data networks. Communications over the networks may include one or more different protocols, such as Institute of Electrical and Electronics Engineers (IEEE) 802.11 family of standards known as Wi-Fi, IEEE 802.16 family of standards known as WiMax, IEEE 802.16.4 family of standards, a Long Term Evolution (LTE) family of standards, a Universal Mobile Telecommunications System (UMTS) family of standards, peer-to-peer (P2P) networks, a next generation (NG)/6^{th} generation (6G) standards among others. In an example, the network interface device 1220 may include one or more physical jacks (e.g., Ethernet, coaxial, or phone jacks) or one or more antennas to connect to the transmission medium 1226.

Note that the term “circuitry” as used herein refers to, is part of, or includes hardware components such as an electronic circuit, a logic circuit, a processor (shared, dedicated, or group) and/or memory (shared, dedicated, or group), an Application Specific Integrated Circuit (ASIC), a field-programmable device (FPD) (e.g., a field-programmable gate array (FPGA), a programmable logic device (PLD), a complex PLD (CPLD), a high-capacity PLD (HCPLD), a structured ASIC, or a programmable SoC), digital signal processors (DSPs), etc., that are configured to provide the described functionality. In some embodiments, the circuitry may execute one or more software or firmware programs to provide at least some of the described functionality. The term “circuitry” may also refer to a combination of one or more hardware elements (or a combination of circuits used in an electrical or electronic system) with the program code used to carry out the functionality of that program code. In these embodiments, the combination of hardware elements and program code may be referred to as a particular type of circuitry.

The term “processor circuitry” or “processor” as used herein thus refers to, is part of, or includes circuitry capable of sequentially and automatically carrying out a sequence of arithmetic or logical operations, or recording, storing, and/or transferring digital data. The term “processor circuitry” or “processor” may refer to one or more application processors, one or more baseband processors, a physical central processing unit (CPU), a single- or multi-core processor, and/or any other device capable of executing or otherwise operating computer-executable instructions, such as program code, software modules, and/or functional processes.

The camera 1228 may sense light at least the wavelength or wavelengths emitted by the LEDs. The camera 1228 may include optics (e.g., at least one camera lens) that are able to collect reflected light of illumination that is reflected from and/or emitted by an illuminated region. The camera lens may direct the reflected light onto a multi-pixel sensor (also referred to as a light sensor) to form an image of on the multi-pixel sensor.

The processor 1202 may control and drive the LEDs via one or more drivers. For example, the processor 1202 may optionally control one or more LEDs in LED arrays independent of another one or more LEDs in the LED arrays, so as to illuminate an area in a specified manner.

In addition, the sensors 1230 may be incorporated in the camera 1228 and/or the light source 1210. The sensors 1230 may sense visible and/or infrared light and may further sense the ambient light and/or variations/flicker in the ambient light in addition to reception of the reflected light from the LEDs. The sensors may have one or more segments (that are able to sense the same wavelength/range of wavelengths or different wavelength/range of wavelengths), similar to the LED arrays.

FIG. 13 illustrates an example lighting system, according to some embodiments. As above, some of the elements shown in the lighting system 1300 may not be present, while other additional elements may be disposed in the lighting system 1300. The lighting system 1300 may include a controller 1302 that controls illumination using a pixel array 1310 that contains multiple individual pixels 1312.

In some embodiments, some or all of the components described as the controller 1302 may be disposed on a backplane such as, for example, a complementary metal oxide semiconductor (CMOS) backplane. The controller 1302 may be coupled to or include one or more processors 1304. The processor 1304 may receive image data (in frames) via an interface and may process the image data to control a generator 1306a, for example, controlling analog signals or PWM duty cycles and/or turn-on times for causing the lighting system 1300 to produce the images indicated by the image data.

The controller 1302 may further include a frame buffer 1308. The frame buffer 1308 may store one or more images prior to the one or more processors 1304 and store the indications for implementation by the one or more processors 1304.

The generator 1306a may be controlled by the processor 1304 and may produce driving signals in accordance with the indications. The generator 1306a may be connected to a driver 1306b to drive the pixel array 1310 so that the pixels 1312 provide desired intensities of light.

Each pixel 1312 may include one or more LEDs 1314. The LEDs 1314 may be different colors and may be controlled individually or in groups. As shown, the pixel 1312 may include, for each pixel 1312 or LED 1314, a PWM switch, and a current source. The pixel 1312 may be driven by the driver 1306b. The signal from the generator 1306a may cause the switch to open and close in accordance with the value of the signal. The signal corresponding to the intensities of light may cause the current source to produce a current flow to cause the pixels 1312 to produce the corresponding intensities of light.

The lighting system 1300 may further include a power supply 1320. In some embodiments, the power supply 1320 may be a battery that produces power for the controller 1302.

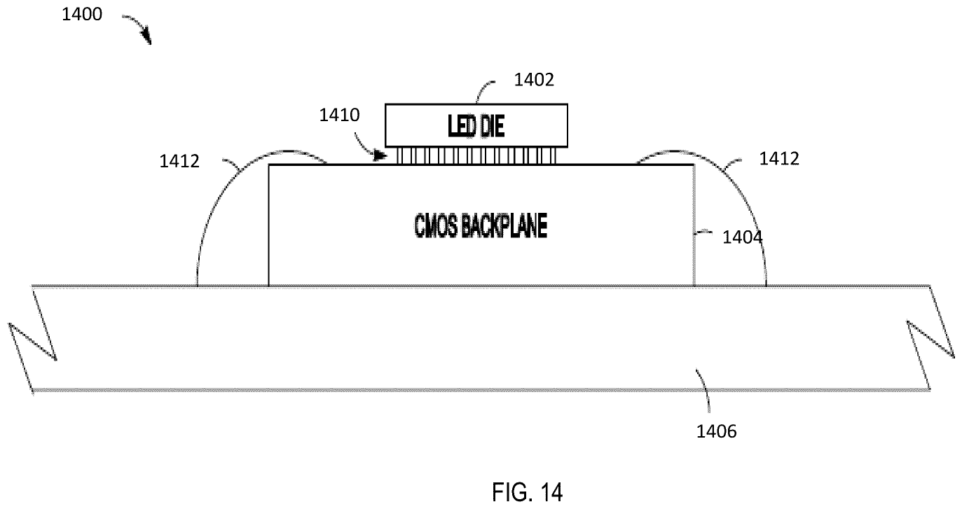

FIG. 14 illustrates an example hardware arrangement for implementing the above disclosed subject matter, according to some embodiments. In particular, the hardware arrangement 1400 may include an LED die 1402 that contains the LED array(s) and a backplane, such as a CMOS backplane 1404. The LED die 1402 may be coupled to the CMOS backplane 1404 by one or more interconnects 1410, where the interconnects 1410 may provide for transmission of signals between the LED die 1402 and the CMOS backplane 1404. The interconnects 1410 may comprise one or more solder bump joints, one or more copper pillar bump joints, other types of interconnects known in the art, or some combination thereof.

The LED die 1402 may include circuitry to implement the LED array described above. In particular, the LED die 1402 may include a plurality of LEDs. The LED die 1402 may include a shared active layer and a shared substrate for the LED array, and thereby the LED array may be a monolithic LED array. Each LED of the LED array may include an individual segmented active layer and/or substrate. In some embodiments, the LED die 1402 may further include switches and current sources to drive the LED array as described above. In other embodiments, the switches and the current sources may be included in the CMOS backplane 1404. The LEDs may be micro-LEDs or LEDs larger than micro-LEDs.

The CMOS backplane 1404 may include circuitry to implement the control module. The CMOS backplane 1404 may utilize the interconnects 1410 to provide the LED array with the driving signals and the signals for the intensity for causing the LED array to produce light in accordance with the signals and the intensity.

The hardware arrangement 1400 may further include a PCB 1406. The PCB 1406 may include circuitry to implement various functionality described herein. The PCB 1406 may be coupled to the CMOS backplane 1404. For example, the PCB 1406 may be coupled to the CMOS backplane 1404 via one or more wire bonds 1412. The PCB 1406 and the CMOS backplane 1404 may exchange image data, power, and/or feedback via the coupling, among other signals.

As shown, the LEDs and circuitry supporting the LED array can be packaged and include a submount or printed circuit board for powering and controlling light production by the LEDs. The PCB supporting the LED array may include electrical vias, heat sinks, ground planes, electrical traces, and flip chip or other mounting systems. The submount or PCB may be formed of any suitable material, such as ceramic, silicon, aluminum, etc. If the submount material is conductive, an insulating layer may be formed over the substrate material, and a metal electrode pattern formed over the insulating layer for contact with the micro-LED array. The submount can act as a mechanical support, providing an electrical interface between electrodes on the LED array and a power supply, and also provide heat sink functionality.

In general, a variety of applications may be supported by LED arrays. Such applications may include stand-alone applications to provide general illumination (e.g., within or external to a room or vehicle) or to provide specific images. In addition to devices such as a luminaire, projector, mobile device, the system may be used to provide AR and VR-based applications. Visualization systems, such as VR and AR systems, are becoming increasingly more common across numerous fields such as entertainment, education, medicine, and business. Various types of devices may be used to provide ARNR to users, including headsets, glasses, and projectors. Such an ARNR system may include components similar to those described above: the micro-LED array, a display or screen (which may include touchscreen elements), a micro-LED array controller, sensors, and a controller, among others. The ARNR components can be disposed in a single structure, or one or more of the components shown can be mounted separately and connected via wired or wireless communication. Power and user data may be provided to the controller. The user data input can include information provided by audio instructions, haptic feedback, eye or pupil positioning, or connected keyboard, mouse, or game controller. The sensors may include cameras, depth sensors, audio sensors, accelerometers, two or three axis gyroscopes and other types of motion and/or environmental/wearer sensors that provide the user input data. Other sensors can include but are not limited to air pressure, stress sensors, temperature sensors, or any other suitable sensors for local or remote environmental monitoring. In some embodiments, the control input can include detected touch or taps, gestural input, or control based on headset or display position. As another example, based on the one or more measurement signals from one or more gyroscope or position sensors that measure translation or rotational movement, an estimated position of the ARNR system relative to an initial position can be determined.

In some embodiments, the controller may control individual micro-LEDs or one or more groups of LEDs to display content (ARNR and/or non-ARNR) to the user while controlling other LEDs and sensors used in eye tracking to adjust the content displayed. Content display LEDs may be designed to emit light within the visible band (approximately 400 nm to 780 nm) while LEDs used for tracking may be designed to emit light in the IR band (approximately 780 nm to 2,200 nm). In some embodiments, the tracking LEDs and content LEDs may be simultaneously active. In some embodiments, the tracking LEDs may be controlled to emit tracking light during a time period that content LEDs are deactivated and are thus not displaying content to the user. The ARNR system can incorporate optics, such as those described above, and/or an ARNR display, for example to couple light emitted by LED array onto the ARNR display.

In some embodiments, the ARNR controller may use data from the sensors to integrate measurement signals received from the accelerometers over time to estimate a velocity vector and integrate the velocity vector over time to determine an estimated position of a reference point for the ARNR system. In other embodiments, the reference point used to describe the position of the ARNR system can be based on depth sensor, camera positioning views, or optical field flow. Based on changes in position, orientation, or movement of the ARNR system, the system controller can send images or instructions to the light emitting array controller. Changes or modification the images or instructions can also be made by user data input, or automated data input.

In general, in a VR system, a display can present to a user a view of a scene, such as a three-dimensional scene. The user can move within the scene, such as by repositioning the user's head or by walking. The VR system can detect the user's movement and alter the view of the scene to account for the movement. For example, as a user rotates the user's head, the system can present views of the scene that vary in view directions to match the user's gaze. In this manner, the VR system can simulate a user's presence in a three-dimensional scene. Further, a VR system can receive tactile sensory input, such as from wearable position sensors, and can optionally provide tactile feedback to the user.

In an AR system, on the other hand, the display can incorporate elements from the user's surroundings into the view of the scene. For example, the AR system can add textual captions and/or visual elements to a view of the user's surroundings. For example, a retailer can use an AR system to show a user what a piece of furniture would look like in a room of the user's home, by incorporating a visualization of the piece of furniture over a captured image of the user's surroundings. As the user moves around the user's room, the visualization accounts for the user's motion and alters the visualization of the furniture in a manner consistent with the motion. For example, the AR system can position a virtual chair in a room. The user can stand in the room on a front side of the virtual chair location to view the front side of the chair. The user can move in the room to an area behind the virtual chair location to view a back side of the chair. In this manner, the AR system can add elements to a dynamic view of the user's surroundings.

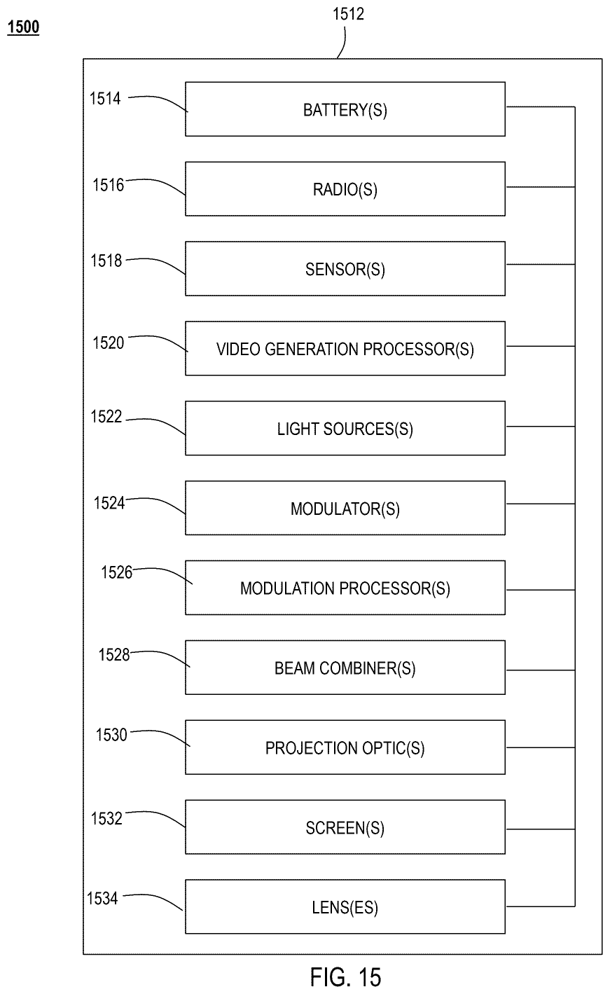

FIG. 15 shows a block diagram of an example of a system, according to some embodiments. The system 1500 may provide ARNR functionality using microLEDs. The system 1500 can include a wearable housing 1512, such as a headset or goggles. The housing 1512 can mechanically support and house the elements detailed below. In some examples, one or more of the elements detailed below can be included in one or more additional housings that can be separate from the wearable housing 1512 and couplable to the wearable housing 1512 wirelessly and/or via a wired connection. For example, a separate housing can reduce the weight of wearable goggles, such as by including batteries, radios, and other elements. The housing 1512 can include one or more batteries 1514, which can electrically power any or all of the elements detailed below. The housing 1512 can include circuitry that can electrically couple to an external power supply, such as a wall outlet, to recharge the batteries 1514. The housing 1512 can include one or more radios 1516 to communicate wirelessly with a server or network via a suitable protocol, such as WiFi.

The system 1500 can include one or more sensors 1518, such as optical sensors, audio sensors, tactile sensors, thermal sensors, gyroscopic sensors, time-of-flight sensors, triangulation-based sensors, and others. In some examples, one or more of the sensors can sense a location, a position, and/or an orientation of a user. In some examples, one or more of the sensors 1518 can produce a sensor signal in response to the sensed location, position, and/or orientation. The sensor signal can include sensor data that corresponds to a sensed location, position, and/or orientation. For example, the sensor data can include a depth map of the surroundings. In some examples, such as for an AR system, one or more of the sensors 1518 can capture a real-time video image of the surroundings proximate a user.

The system 1500 can include one or more video generation processors 1520. The one or more video generation processors 1520 can receive scene data that represents a three-dimensional scene, such as a set of position coordinates for objects in the scene or a depth map of the scene. This data may be received from a server and/or a storage medium. The one or more video generation processors 1520 can receive one or more sensor signals from the one or more sensors 1518. In response to the scene data, which represents the surroundings, and at least one sensor signal, which represents the location and/or orientation of the user with respect to the surroundings, the one or more video generation processors 1520 can generate at least one video signal that corresponds to a view of the scene. In some examples, the one or more video generation processors 1520 can generate two video signals, one for each eye of the user, that represent a view of the scene from a point of view of the left eye and the right eye of the user, respectively. In some examples, the one or more video generation processors 1520 can generate more than two video signals and combine the video signals to provide one video signal for both eyes, two video signals for the two eyes, or other combinations.

The system 1500 can include one or more light sources 1522 that can provide light for a display of the system 1500. Suitable light sources 1522 can include the microLEDs above, for example. The one or more light sources 1522 can include light-producing elements having different colors or wavelengths. For example, a light source can include a red light-emitting diode that can emit red light, a green light-emitting diode that can emit green light, and a blue light-emitting diode that can emit blue light. The red, green, and blue light combine in specified ratios to produce any suitable color that is visually perceptible in a visible portion of the electromagnetic spectrum.

The system 1500 can include one or more modulators 1524. The modulators 1524 can be implemented in one of at least two configurations. In a first configuration, the modulators 1524 can include circuitry that can modulate the light sources 1522 directly. For example, the light sources 1522 can include an array of light-emitting diodes, and the modulators 1524 can directly modulate the electrical power, electrical voltage, and/or electrical current directed to each light-emitting diode in the array to form modulated light. The modulation can be performed in an analog manner and/or a digital manner. In some examples, the light sources 1522 can include an array of red light-emitting diodes, an array of green light-emitting diodes, and an array of blue light-emitting diodes, and the modulators 1524 can directly modulate the red light-emitting diodes, the green light-emitting diodes, and the blue light-emitting diodes to form the modulated light to produce a specified image.

In a second configuration, the modulators 1524 can include a modulation panel, such as a liquid crystal panel. The light sources 1522 can produce uniform illumination, or nearly uniform illumination, to illuminate the modulation panel. The modulation panel can include pixels. Each pixel can selectively attenuate a respective portion of the modulation panel area in response to an electrical modulation signal to form the modulated light. In some examples, the modulators 1524 can include multiple modulation panels that can modulate different colors of light. For example, the modulators 1524 can include a red modulation panel that can attenuate red light from a red-light source such as a red light-emitting diode, a green modulation panel that can attenuate green light from a green light source such as a green light-emitting diode, and a blue modulation panel that can attenuate blue light from a blue light source such as a blue light-emitting diode.

In some examples of the second configuration, the modulators 1524 can receive uniform white light or nearly uniform white light from a white light source, such as a white-light light-emitting diode. The modulation panel can include wavelength-selective filters on each pixel of the modulation panel. The panel pixels can be arranged in groups (such as groups of three or four), where each group can form a pixel of a color image. For example, each group can include a panel pixel with a red color filter, a panel pixel with a green color filter, and a panel pixel with a blue color filter. Other suitable configurations can also be used.

The system 1500 can include one or more modulation processors 1526, which can receive a video signal, such as from the one or more video generation processors 1520, and, in response, can produce an electrical modulation signal. For configurations in which the modulators 1524 directly modulate the light sources 1522, the electrical modulation signal can drive the modulators 1524. For configurations in which the modulators 1524 include a modulation panel, the electrical modulation signal can drive the modulation panel.

The system 1500 can include one or more beam combiners 1528 (also known as beam splitters), which can combine light beams of different colors to form a single multi-color beam. For configurations in which the light sources 1522 can include multiple light-emitting diodes of different colors, the system 500 can include one or more wavelength-sensitive (e.g., dichroic) beam combiners 1528 that can combine the light of different colors to form a single multi-color beam.

The system 1500 can direct the modulated light toward the eyes of the viewer in one of at least two configurations. In a first configuration, the system 1500 can function as a projector, and can include suitable projection optics 1530 that can project the modulated light onto one or more screens 1532. The screens 1532 can be located a suitable distance from the eye of the user. The system 1500 can optionally include one or more lenses 1534 that can locate a virtual image of a screen 1532 at a suitable distance from the eye, such as a close-focus distance, such as 500 mm, 750 mm, or another suitable distance. In some examples, the system 1500 can include a single screen 1532, such that the modulated light can be directed toward both eyes of the user. In some examples, the system 1500 can include two screens 1532, such that the modulated light from each screen 1532 can be directed toward a respective eye of the user. In some examples, the system 1500 can include more than two screens 1532. In a second configuration, the system 500 can direct the modulated light directly into one or both eyes of a viewer. For example, the projection optics 1530 can form an image on a retina of an eye of the user, or an image on each retina of the two eyes of the user.

For some configurations of AR systems, the system 1500 can include at least a partially transparent display, such that a user can view the user's surroundings through the display. For such configurations, the AR system can produce modulated light that corresponds to the augmentation of the surroundings, rather than the surroundings itself. For example, in the example of a retailer showing a chair, the AR system can direct modulated light, corresponding to the chair but not the rest of the room, toward a screen or toward an eye of a user.

### Embodiments

Various embodiments are listed below. It will be understood that the embodiments listed below may be combined with all aspects and other embodiments in accordance with the scope of the invention.

Embodiment (a). A light-emitting diode (LED) device comprising: three p-n junctions grown sequentially on a substrate, the three p-n junctions including: a first p-n junction comprising a first light-emitting active region, a second p-n junction comprising a second light-emitting active region, and a third p-n junction comprising a third light-emitting active region, each of the three p-n junctions comprising an n-type layer and a p-type layer, one of the first p-n junction, the second p-n junction, or the third p-n junction having an n-type layer and a p-type layer grown in the opposite order of the n-type layer and p-type layer of the other of the first p-n junction, the second p-n junction, or the third p-n junction; an n/p tunnel junction; a p/n tunnel junction; and a current blocking layer disposed between two of the n-type layers.

Embodiment (b). The LED device of embodiment (a), wherein the first light-emitting active region, the second light-emitting active region, and the third light-emitting active region independently comprise a blue active region, a green active region, or a red active region.

Embodiment (c). The LED device of embodiment (a) to embodiment (b), wherein the one of the p-type layers or the n-type layers comprise a diffusion blocking layer.

Embodiment (d). The LED device of embodiment (a) to embodiment (c), wherein the diffusion blocking layer comprises one or more of a short-period superlattice of semiconductor alloy layers having different lattice constants, or layers co-doped with magnesium (Mg) and silicon (Si), a concentration of magnesium (Mg) greater than a concentration of silicon (Si).

Embodiment (e). The LED device of embodiment (a) to embodiment (d), further comprising a second p/n tunnel junction.

Embodiment (f). The LED device of embodiment (a) to embodiment (e), further comprising a transparent conductive oxide layer on one of the p-type layers.

Embodiment (g). The LED device of embodiment (a) to embodiment (f), wherein the n-type layers independently comprise one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like.

Embodiment (h). The LED device of embodiment (a) to embodiment (g), wherein the n-type layers comprise gallium nitride (GaN).

Embodiment (i). The LED device of embodiment (a) to embodiment (h), further comprising five terminals filled with one or more of an anode metal layer or a cathode metal layer.

Embodiment (j). The LED device of embodiment (a) to embodiment (i), wherein the cathode metal layer and the anode metal layer independently comprise one or more of aluminum (Al) or silver (Ag).

Embodiment (k). The LED device of embodiment (a) to embodiment (j), further comprising a dielectric layer in the five terminals.

Embodiment (l). The LED device of embodiment (a) to embodiment (k), wherein the one of the five terminals comprises a common cathode.

Embodiment (m). The LED device of embodiment (a) to embodiment (l), wherein one of the five terminals comprises a common anode.

Embodiment (n). A method of manufacturing a light-emitting diode (LED) device, the method comprising: epitaxially growing an epitaxial stack on a substrate, the epitaxial stack comprising three p-n junctions grown sequentially on the substrate, an n/p tunnel junction, a p/n tunnel junction, and a current blocking layer, wherein the three p-n junctions include a first p-n junction comprising a first light-emitting active region, a second p-n junction comprising a second light-emitting active region, and a third p-n junction comprising a third light-emitting active region, wherein one of the first p-n junction, the second p-n junction, or the third p-n junction has n-type layers and p-type layers grown in the opposite order of the n-type layers and p-type layers of the other of the first p-n junction, the second p-n junction, or the third p-n junction, and wherein the current blocking layer is disposed between two of the n-type layers.

Embodiment (o). The method of embodiment (n), wherein the first light-emitting active region, the second light-emitting active region, and the third light-emitting active region independently comprise a blue active region, a green active region, or a red active region.

Embodiment (p). The method of embodiment (n) to embodiment (o), wherein the one of the p-type layers or the n-type layers comprise a diffusion blocking layer.

Embodiment (q). The method of embodiment (n) to embodiment (p), wherein the diffusion blocking layer comprises one or more of a short-period superlattice of semiconductor alloy layers having different lattice constants, or layers co-doped with magnesium (Mg) and silicon (Si), a concentration of magnesium (Mg) greater than a concentration of silicon (Si).

Embodiment (r). The method of embodiment (n) to embodiment (q), wherein the epitaxial stack further comprises a second p/n tunnel junction.

Embodiment (s). The method of embodiment (n) to embodiment (r), further comprising forming five terminals on the epitaxial stack, one of the five terminals comprising a common cathode or a common anode.

Embodiment (t). The method of embodiment (n) to embodiment (s), further comprising forming a transparent conductive oxide layer on one of the p-type layers of the epitaxial stack.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to the terms first, second, third, etc. may be used herein to describe various elements, and these elements should not be limited by these terms. These terms may be used to distinguish one element from another.

Reference throughout this specification to a layer, region, or substrate as being “on” or extending “onto” another element, means that it may be directly on or extend directly onto the other element or intervening elements may also be present. When an element is referred to as being “directly on” or extending “directly onto” another element, there may be no intervening elements present. Furthermore, when an element is referred to as being “connected” or “coupled” to another element, it may be directly connected or coupled to the other element and/or connected or coupled to the other element via one or more intervening elements. When an element is referred to as being “directly connected” or “directly coupled” to another element, there are no intervening elements present between the element and the other element. It will be understood that these terms are intended to encompass different orientations of the element in addition to any orientation depicted in the figures.

Relative terms such as “below,” “above,” “upper,”, “lower,” “horizontal” or “vertical” may be used herein to describe a relationship of one element, layer, or region to another element, layer, or region as illustrated in the figures. It will be understood that these terms are intended to encompass different orientations of the device in addition to the orientation depicted in the figures.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A light-emitting diode (LED) device comprising:
three p-n junctions grown sequentially on a substrate, the three p-n junctions including:
a first p-n junction comprising a first light-emitting active region,
a second p-n junction comprising a second light-emitting active region, and
a third p-n junction comprising a third light-emitting active region,
each of the three p-n junctions comprising an n-type layer and a p-type layer,
one of the first p-n junction, the second p-n junction, or the third p-n junction having an n-type layer and a p-type layer grown in the opposite order of the n-type layer and p-type layer of the other of the first p-n junction, the second p-n junction, or the third p-n junction;
an n/p tunnel junction;
a p/n tunnel junction; and
a current blocking layer disposed between two of the n-type layers.

2. The LED device of claim 1, wherein the first light-emitting active region, the second light-emitting active region, and the third light-emitting active region independently comprise a blue active region, a green active region, or a red active region.

3. The LED device of claim 1, wherein the one of the p-type layers or the n-type layers comprise a diffusion blocking layer.

4. The LED device of claim 3, wherein the diffusion blocking layer comprises one or more of a short-period superlattice of semiconductor alloy layers having different lattice constants, or layers co-doped with magnesium (Mg) and silicon (Si), a concentration of magnesium (Mg) greater than a concentration of silicon (Si).

5. The LED device of claim 1, further comprising a second p/n tunnel junction.

6. The LED device of claim 1, further comprising a transparent conductive oxide layer on one of the p-type layers.

7. The LED device of claim 1, wherein the n-type layers independently comprise one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like.

8. The LED device of claim 7, wherein the n-type layers comprise gallium nitride (GaN).

9. The LED device of claim 1, further comprising five terminals filled with one or more of an anode metal layer or a cathode metal layer.

10. The LED device of claim 9, wherein the cathode metal layer and the anode metal layer independently comprise one or more of aluminum (Al) or silver (Ag).

11. The LED device of claim 9, further comprising a dielectric layer in the five terminals.

12. The LED device of claim 9, wherein the one of the five terminals comprises a common cathode.

13. The LED device of claim 9, wherein one of the five terminals comprises a common anode.

14. A method of manufacturing a light-emitting diode (LED) device, the method comprising:
epitaxially growing an epitaxial stack on a substrate, the epitaxial stack comprising three p-n junctions grown sequentially on the substrate, an n/p tunnel junction, a p/n tunnel junction, and a current blocking layer,
wherein the three p-n junctions include a first p-n junction comprising a first light-emitting active region, a second p-n junction comprising a second light-emitting active region, and a third p-n junction comprising a third light-emitting active region,
wherein one of the first p-n junction, the second p-n junction, or the third p-n junction has n-type layers and p-type layers grown in the opposite order of the n-type layers and p-type layers of the other of the first p-n junction, the second p-n junction, or the third p-n junction, and
wherein the current blocking layer is disposed between two of the n-type layers.

15. The method of claim 14, wherein the first light-emitting active region, the second light-emitting active region, and the third light-emitting active region independently comprise a blue active region, a green active region, or a red active region.

16. The method of claim 14, wherein the one of the p-type layers or the n-type layers comprise a diffusion blocking layer.

17. The method of claim 16, wherein the diffusion blocking layer comprises one or more of a short-period superlattice of semiconductor alloy layers having different lattice constants, or layers co-doped with magnesium (Mg) and silicon (Si), a concentration of magnesium (Mg) greater than a concentration of silicon (Si).

18. The method of claim 14, wherein the epitaxial stack further comprises a second p/n tunnel junction.

19. The method of claim 14, further comprising forming five terminals on the epitaxial stack, one of the five terminals comprising a common cathode or a common anode.

20. The method of claim 14, further comprising forming a transparent conductive oxide layer on one of the p-type layers of the epitaxial stack.
